(19) United States
(12) Patent Application Publication
(10) Pub. No.: US 2024/0164013 A1
(43) Pub. Date: May 16, 2024

(54) PRINTED CIRCUIT BOARD AND MANUFACTURING METHOD FOR THE SAME

(71) Applicant: SAMSUNG ELECTRO-MECHANICS CO., LTD., Suwon-si (KR)

(72) Inventors: Jae Heun LEE, Suwon-si (KR); Jong Eun PARK, Suwon-si (KR); Chan Jin PARK, Suwon-si (KR); Hyun Seok YANG, Suwon-si (KR); Tae Hee YOO, Suwon-si (KR)

(73) Assignee: SAMSUNG ELECTRO-MECHANICS CO., LTD., Suwon-si (KR)

(21) Appl. No.: 18/221,001

(22) Filed: Jul. 12, 2023

(30) Foreign Application Priority Data
Nov. 16, 2022 (KR) 10-2022-0153872
Jan. 9, 2023 (KR) 10-2023-0002642

(51) Int. Cl. H05K 1/02; H05K 3/18; H05K 3/26

(52) U.S. Cl. CPC H05K 1/0298; H05K 3/181; H05K 3/26

(57) ABSTRACT

A printed circuit board including a first insulating layer; a plurality of first circuit patterns respectively disposed on the first insulating layer; a second insulating layer disposed on the first insulating layer and covering a portion of a side surface of each of the plurality of first circuit patterns; and an insulator disposed between at least one pair of adjacent first circuit patterns, among the plurality of first circuit patterns, and integrated with the first insulating layer, and a method for manufacturing a printed circuit board, are provided.

### CROSS-REFERENCE TO RELATED APPLICATION(S)

This application claims benefit of priorities to Korean Patent Application No. 10-2022-0153872 filed on Nov. 16, 2022 and Korean Patent Application No. 10-2023-0002642 filed on Jan. 9, 2023 in the Korean Intellectual Property Office, the disclosures of which are incorporated herein by reference in their entireties.

### TECHNICAL FIELD

The present disclosure relates to a printed circuit board, for example, a printed circuit board including a microcircuit, and a manufacturing method thereof.

Recently, in the electronic components industry, highly integrated printed circuit boards have been required to cope with 5G high-speed communications and artificial intelligence. A microcircuit is a key technology for manufacturing highly integrated printed circuit boards, and, for example, research and development is actively underway to secure technologies capable of implementing microcircuits with a line/space of approximately several microns. However, in conventional circuit formation methods, such as a semi-additive process (SAP), a modified semi-additive process (MSAP), an embedded trace substrate (ETS), or the like, there are limitations in implementing the microcircuits having the above-described range of line/space due to a limit to resolution of exposure equipment and margin of the seed etching process, and reliability may deteriorate due to recess step differences and circuit thickness deviations inevitably occurring during a seed etching process.

### SUMMARY

One of the various objects of the present disclosure is provide a printed circuit board capable of forming a microcircuit and a manufacturing method thereof.

Another object of the present disclosure is to provide a printed circuit board having high reliability and a manufacturing method thereof.

One of various solutions proposed by the present disclosure is to prepare a microcircuit by exposing and developing a dry film, such that a ratio of line/space is higher than 1:1, to form a plurality of dry film patterns, forming a seed metal layer thereon, forming a plating layer having a substantially constant thickness on the seed metal layer, covering the plating layer with a second insulating layer, performing primary polishing, removing the plurality of dry film patterns, covering with a first insulating layer, and then performing secondary polishing.

For example, a method of manufacturing a printed circuit board according to an example includes forming a first dry film on a detachable substrate; forming a plurality of dry film patterns spaced apart from each other on the detachable substrate by patterning the first dry film; forming a seed metal layer covering each of the plurality of dry film patterns on the detachable substrate; forming a first plating layer on the seed metal layer along the detachable substrate and the plurality of dry film patterns; forming a second insulating layer on the first plating layer to cover the first plating layer and to fill a space between side surfaces of the first plating layer, facing each other and distant from the seed metal layer; polishing at least a portion of the second insulating layer, at least a portion of the first plating layer, and at least a portion of the seed metal layer; removing the plurality of dry film patterns remaining between side surfaces of the seed metal layer, facing each other and distant from the first plating layer; forming a first insulating layer on the detachable substrate to cover the second insulating layer and the first plating layer and to fill a space between the side surfaces of the seed metal layer; removing the detachable substrate; and polishing at least a portion of the seed metal layer, at least a portion of the first plating layer, and at least a portion of the first insulating layer.

In addition, a printed circuit board according to an example includes a first insulating layer; a plurality of first circuit patterns respectively disposed on the first insulating layer; a second insulating layer disposed on the first insulating layer and covering a portion of a side surface of each of the plurality of first circuit patterns; and an insulator disposed between at least one pair of adjacent first circuit patterns, among the plurality of first circuit patterns, and integrated with the first insulating layer.

In addition, a printed circuit board according to an example includes an insulating material; and a plurality of first circuit patterns respectively embedded in the insulating material. A seed metal layer is disposed on one side surface, of at least one pair of adjacent first circuit patterns, among the plurality of first circuit patterns, respectively facing each other, and the seed metal layer is not disposed on the other side surface, opposite to the one side surface.

A printed circuit board according to an example includes a first insulating layer including a base portion and a protruding portion protruding from the base portion; a second insulating layer disposed on the base portion of the first insulating layer and including an opening in which the protruding portion of the first insulating layer is disposed; first circuit patterns spaced apart from each other, and disposed in the opening and on opposing side surfaces of the protruding portion of the first insulating layer, respectively.

A printed circuit board according to an example includes a first insulating layer including a base portion and protruding portions protruding from the base portion; first circuit patterns disposed on the base portion of the first insulating layer and spaced apart from each other in one direction; and a second insulating layer disposed on the first insulating layer. The second insulating layer includes portions alternately disposed with the protruding portions of the first insulating layer in the one direction to separate adjacent two of the first circuit patterns from each other in the one direction.

### BRIEF DESCRIPTION OF DRAWINGS

The above and other aspects, features, and advantages of the present disclosure will be more clearly understood from the following detailed description, taken in conjunction with the accompanying drawings.

FIG. 1 is a block diagram schematically illustrating an example of an electronic device system.

FIG. 2 is a perspective view schematically illustrating an example of an electronic device.

FIG. 3 is a schematic cross-sectional view of an example of a printed circuit board.

FIG. 4 is a plan view illustrating a schematic plan view of the printed circuit board of FIG. 3.

FIGS. 5A to 5K are process diagrams schematically illustrating an example of manufacturing the printed circuit board of FIGS. 3 and 4.

FIGS. 6A to 6E are process diagrams schematically illustrating an example of the cut etching of FIG. 5E.

FIG. 7 is a schematic cross-sectional view of another example of a printed circuit board.

FIG. 8 is a plan view illustrating a schematic plan view of the printed circuit board of FIG. 7.

FIGS. 9A to 9I are process diagrams schematically illustrating an example of manufacturing the printed circuit board of FIGS. 7 and 8.

FIG. 10 is a schematic cross-sectional view of another example of a printed circuit board.

FIGS. 11A to 11C are process diagrams schematically illustrating an example of manufacturing the printed circuit board of FIG. 10.

FIG. 12 is a schematic cross-sectional view of another example of a printed circuit board.

FIGS. 13A to 13C are process diagrams schematically illustrating an example of manufacturing the printed circuit board of FIG. 12.

FIG. 14 is a schematic cross-sectional view of another example of a printed circuit board.

FIGS. 15A to 15F are process diagrams schematically illustrating an example of manufacturing the printed circuit board of FIG. 14.

### DETAILED DESCRIPTION

Hereinafter, the present disclosure will be described with reference to the accompanying drawings. Shapes and sizes of elements in the drawings may be exaggerated or reduced for clarity.

Electronic Device

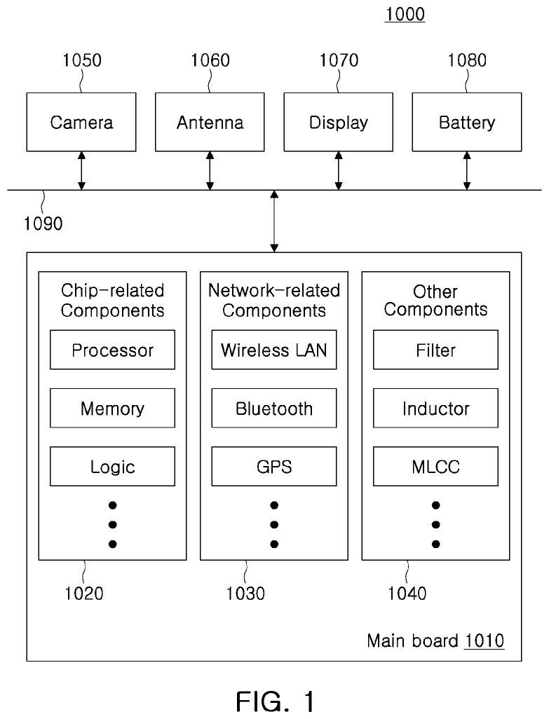

FIG. 1 is a block diagram schematically illustrating an example of an electronic device system.

Referring to the drawing, an electronic device 1000 may accommodate a main board 1010 therein. The main board 1010 may include chip related components 1020, network related components 1030, other components 1040, and the like, physically and/or electrically connected thereto. These components may be connected to others to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital converter, an application-specific integrated circuit (ASIC), or the like. However, the chip related components 1020 are not limited thereto, but may also include other types of chip related components. In addition, the chip related components 1020 may be combined with each other. The chip related component 1020 may be in the form of a package including the above-described chip or an electronic component.

The network related components 1030 may include components compatible with or communicating using various protocols such as wireless fidelity (Wi-Fi) (Institute of Electrical and Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, but may also include components compatible with or communicating using a variety of other wireless or wired standards or protocols. In addition, the network related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, but may also include passive components used for various other purposes, or the like. In addition, other components 1040 may be combined with each other, together with the chip related components 1020 and/or the network related components 1030 described above.

Depending on a type of the electronic device 1000, the electronic device 1000 may include other components that may or may not be physically and/or electrically connected to the main board 1010. These other components may include, for example, a camera module 1050, an antenna module 1060, a display device 1070, a battery 1080, or the like. However, these other components are not limited thereto, but may also include an audio codec, a video codec, a power amplifier, a compass, an accelerometer, a gyroscope, a speaker, a mass storage unit (for example, a hard disk drive), a compact disk (CD) drive, a digital versatile disk (DVD) drive, or the like. These other components may also include other components used for various purposes depending on a type of electronic device 1000, or the like.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, but may be any other electronic device processing data.

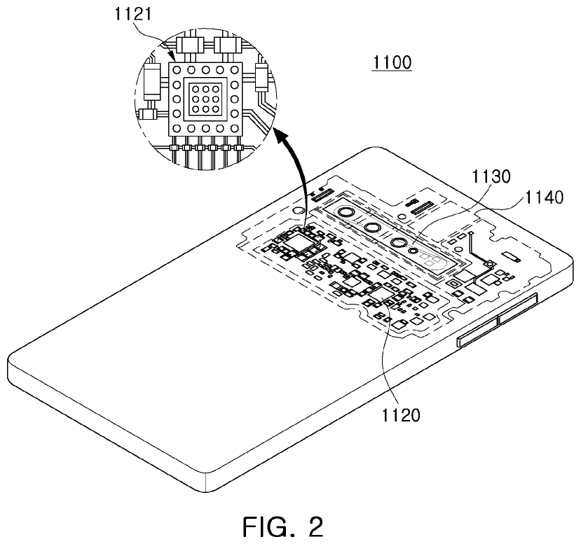

FIG. 2 is a perspective view schematically illustrating an example of an electronic device.

Referring to the drawings, an electronic device may be, for example, a smartphone 1100. A motherboard 1110 may be accommodated inside the smartphone 1100, and various components 1120 may be physically and/or electrically connected to the motherboard 1110. In addition, other components, such as a camera module 1130 and/or a speaker 1140, that may or may not be physically and/or electrically connected to the motherboard 1110, may be accommodated therein. A portion of the components 1120 may be the aforementioned chip-related components, for example, a component package 1121, but are not limited thereto. The component package 1121 may be provided as a printed circuit board on which electronic components including active components and/or passive components are surface mounted. Alternatively, the component package 1121 may be provided as a printed circuit board in which active components and/or passive components are embedded. The electronic device is not necessarily limited to the smartphone 1100, but may be other electronic devices as described above.

Printed Circuit Board

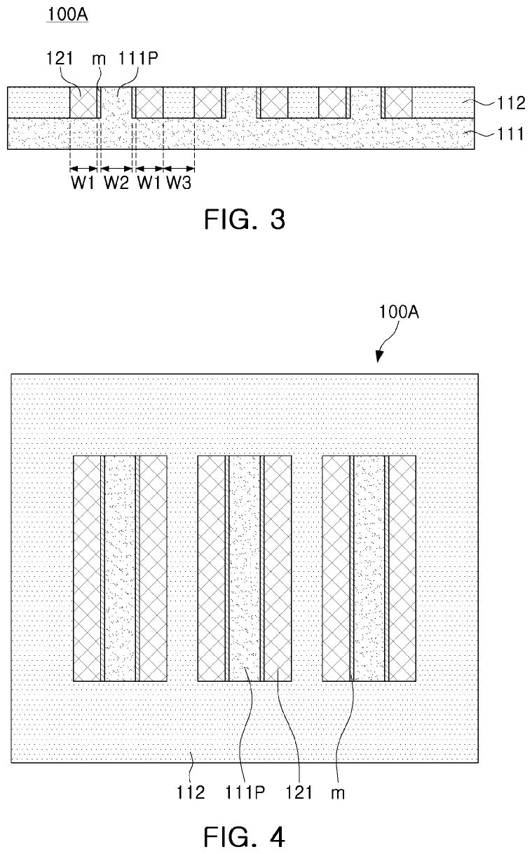

FIG. 3 is a schematic cross-sectional view of an example of a printed circuit board.

FIG. 4 is a plan view illustrating a schematic plan view of the printed circuit board of FIG. 3.

Referring to the drawings, a printed circuit board 100A according to an example may include a first insulating layer 111, a plurality of first circuit patterns 121 respectively disposed on the first insulating layer 111, and a second insulating layer 112 disposed on the first insulating layer 111 and covering a portion of a side surface of each of the plurality of first circuit patterns 121. A portion of the first insulating layer 111, for example, an insulator 111P, as a protruding portion of the first insulating layer 111 protruding from a base portion of the first insulating layer 111, may be disposed to extend between at least one pair of adjacent first circuit patterns 121, among the plurality of first circuit patterns 121. An interlayer interface, e.g., a boundary, may exist between the first and second insulating layers 111 and 112. An interlayer interface, e.g., a boundary, may not exist between the first insulating layer 111 and the insulator 111P. For example, the insulator 111P and the first insulating layer 111 may be integrated with each other without a boundary.

The insulator 111P may be disposed between one side surfaces of the at least one pair of adjacent first circuit patterns 121. In one example, the at least one pair of adjacent first circuit patterns 121 and the insulator 111P therebetween may be disposed in an opening of the second insulating layer 112. In this case, the second insulating layer 112 may cover the other side surface of each of the at least one pair of adjacent first circuit patterns 121. In this case, one first circuit pattern among the at least one pair of adjacent first circuit patterns 121, the insulator 111P, the other first circuit pattern among the at least one pair of adjacent first circuit patterns 121, and the second insulating layer 112 may be repeatedly arranged at least twice in order in cross-sectional view. Each of the at least one pair of adjacent first circuit patterns 121 may have substantially the same line width in cross-sectional view, and thus circuit patterns 121 having a constant line width may be repeatedly disposed. For example, if a line width of each of the at least one pair of adjacent first circuit patterns 121 is denoted by W1, a width of the insulator 111P is denoted by W2, and a width of the second insulating layer 112 is denoted by W3 in cross-sectional view, the line width or width may be repeated at least twice in order of W1, W2, W1, and W3.

A seed metal layer m may be disposed between the insulator 111P and one side surface of each of the at least one pair of adjacent first circuit patterns 121, each facing each other. The seed metal layer m may not be disposed on the other side surface, opposite to the one side surface, an upper surface, and a lower surface of each of the at least one pair of adjacent first circuit patterns 121.

An upper surface of each of the plurality of first circuit patterns 121, an upper surface of the second insulating layer 112, and an upper surface of the insulator 111P may be substantially coplanar with each other. In addition, a lower surface of each of the plurality of first circuit patterns 121 and a lower surface of the second insulating layer 112 may be substantially coplanar with each other.

The first and second insulating layers 111 and 112 may include insulating materials, different from each other. However, an example is not limited thereto, and may include insulating materials, substantially the same as each other. Even in this case, the above-described interlayer boundary may exist.

A printed circuit board 100A according to an example of such a structure may be formed by a new process to be described later. In this case, unlike conventional SAP, MSAP, ETS, or the like, the printed circuit board 100A may be patterned by exposure and development such that a line/space of a dry film for forming a pattern has a ratio of 1:1 or lower, for example, about 1:3. It is possible to overcome a limitation of resolution of exposure equipment, and a separate seed etching process may not be performed. As a result, a microcircuit having a line/space of, for example, approximately 2 μm/2 μm or less may be easily formed. In addition, since a recess step difference and a circuit thickness deviation, which were unnecessarily generated during a seed etching process of the ETS, may not occur, reliability of a product therefrom may be improved.

Hereinafter, components of a printed circuit board 100A according to an example will be described in more detail with reference to the drawings.

The first and second insulating layers 111 and 112 may include an insulating material, respectively. The insulating material may include a thermosetting resin such as an epoxy resin, a thermoplastic resin such as polyimide, or a material including an inorganic filler, an organic filler, and/or glass fiber (glass cloth, glass fabric) together with a resin. For example, the insulating material may be a non-photosensitive insulating material such as Ajinomoto Build-up Film (ABF), a prepreg (PPG), or the like, but is not limited thereto, and other polymer materials may be used. In addition, the insulating material may be a photosensitive insulating material such as a photoimageable dielectric (PID) or the like. The insulator 111P may include an insulating material, substantially identical to the insulating material of the first insulating layer 111.

Each of the plurality of first circuit patterns 121 may include a metal. The metal may include copper (Cu), aluminum (Al), silver (Ag), tin (Sn), gold (Au), nickel (Ni), lead (Pb), titanium (Ti), and/or alloys thereof, or the like. Preferably, copper (Cu) may be included, but is not limited thereto. The plurality of first circuit patterns 121 may perform various functions according to a design. For example, a signal pattern may be included. Each of the plurality of first circuit patterns 121 may include an electrolytic plating layer (or electrolytic copper).

The seed metal layer m may include a metal. The metal may include copper (Cu), aluminum (Al), silver (Ag), tin (Sn), gold (Au), nickel (Ni), lead (Pb), titanium (Ti), and/or alloys thereof, or the like. Preferably, copper (Cu) may be included, but is not limited thereto. The seed metal layer m may include an electroless plating layer (or chemical copper) or a sputtering layer, preferably a sputtering layer, but is not limited thereto. The sputtering layer may be provided as a single layer or multiple layers. The seed metal layer m may be distinguished from each of the plurality of first circuit patterns 121.

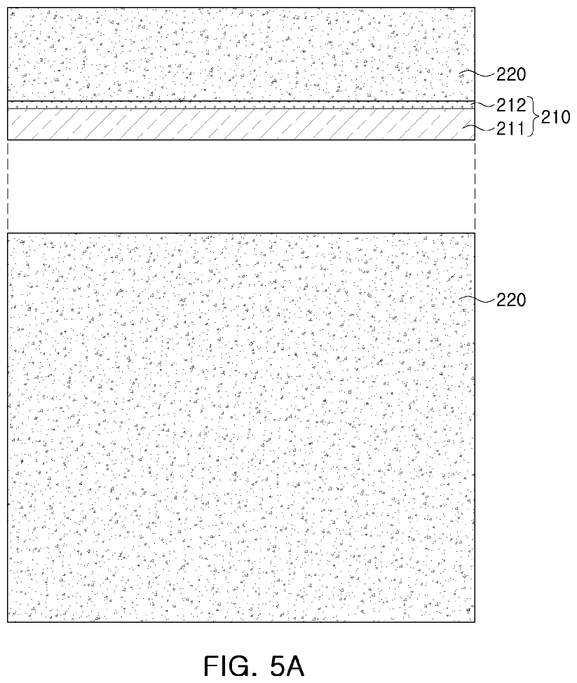

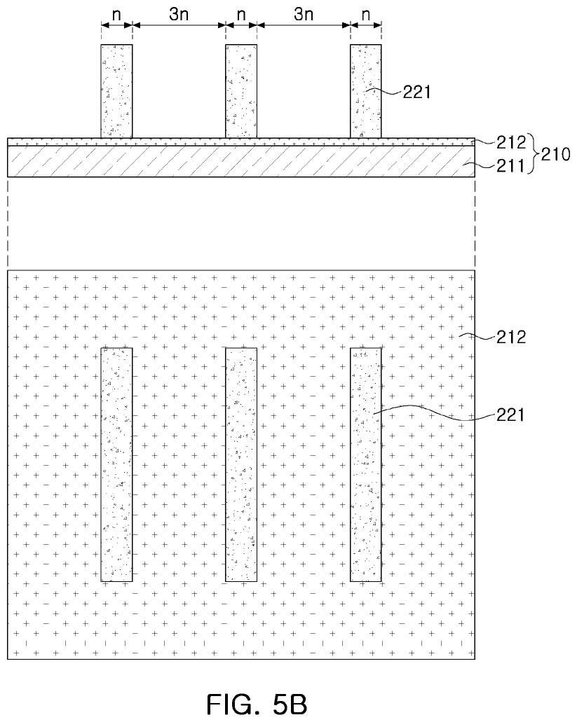

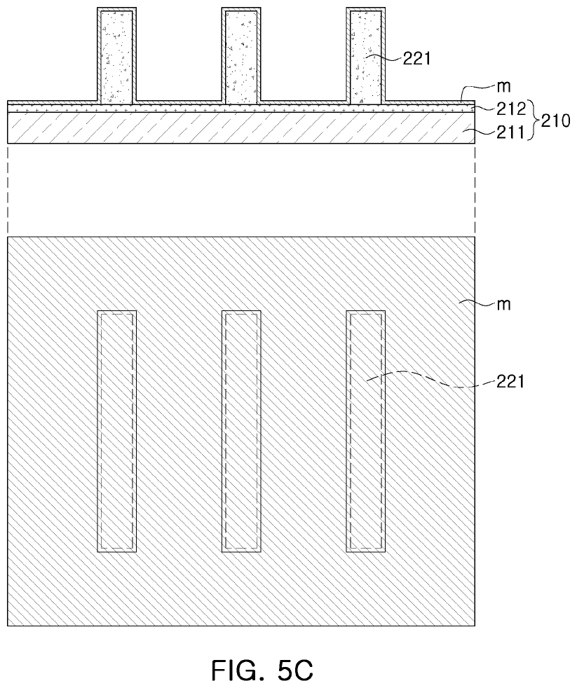

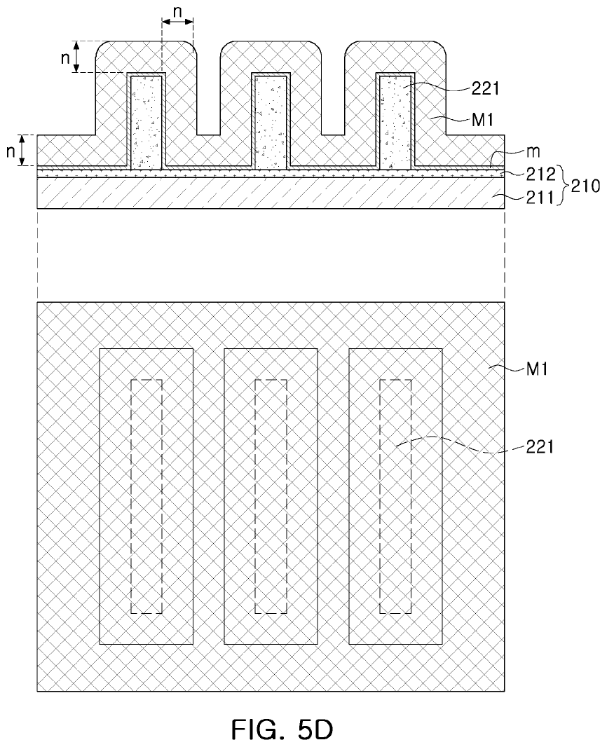

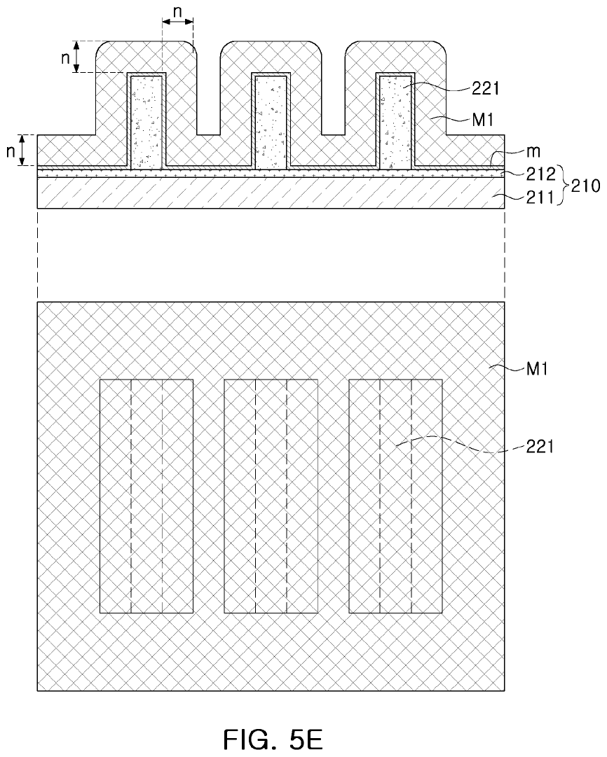

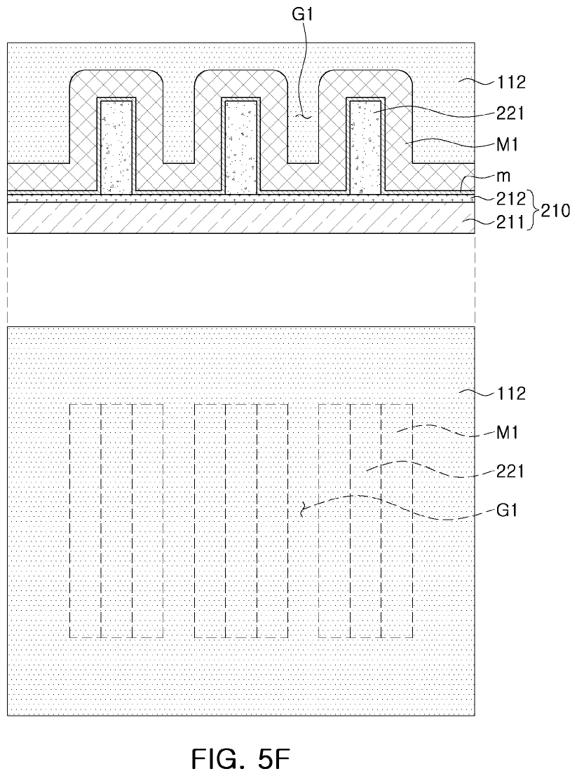

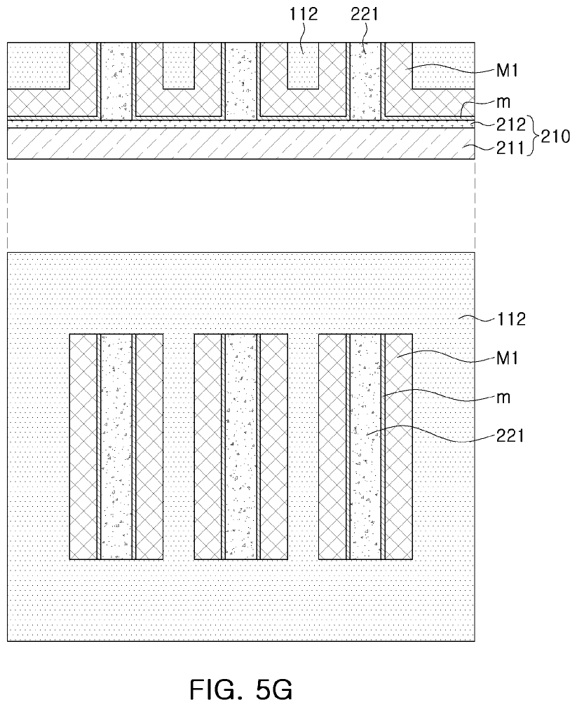

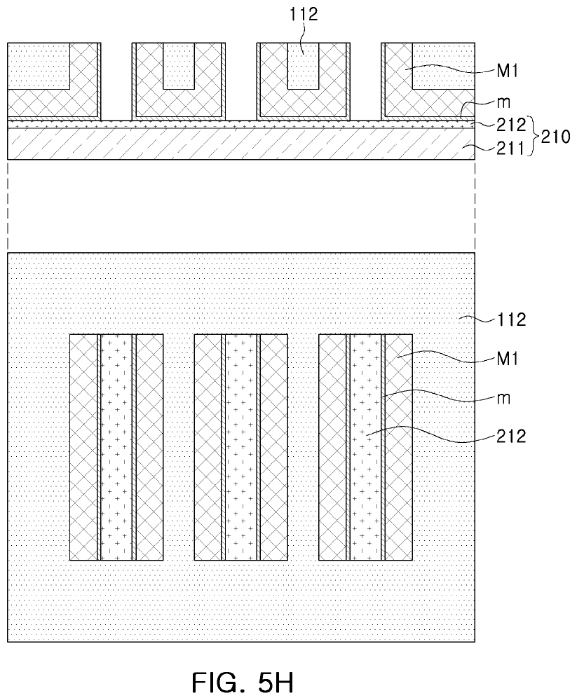

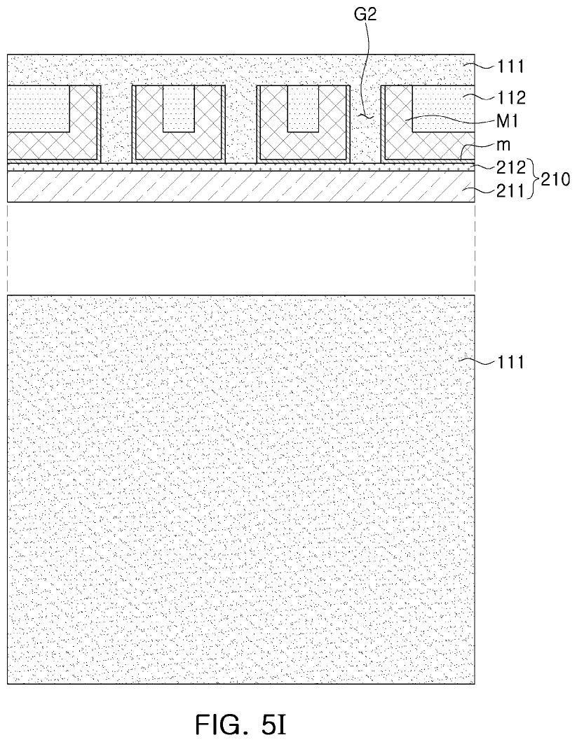

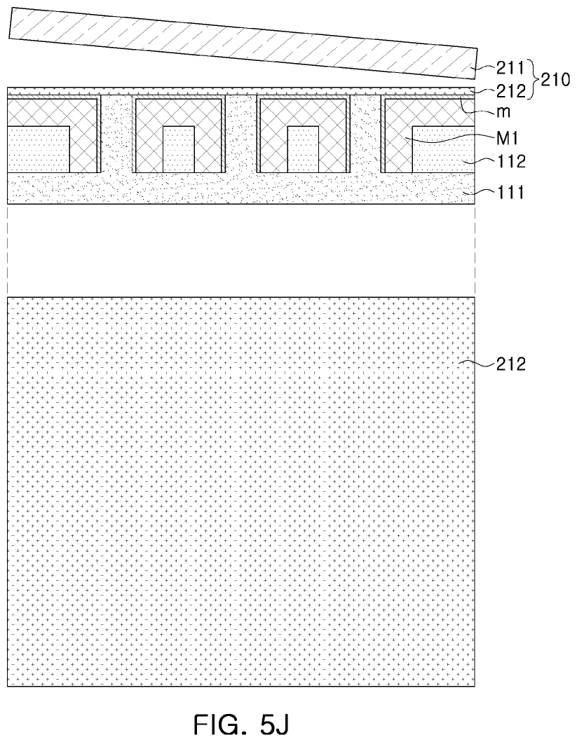

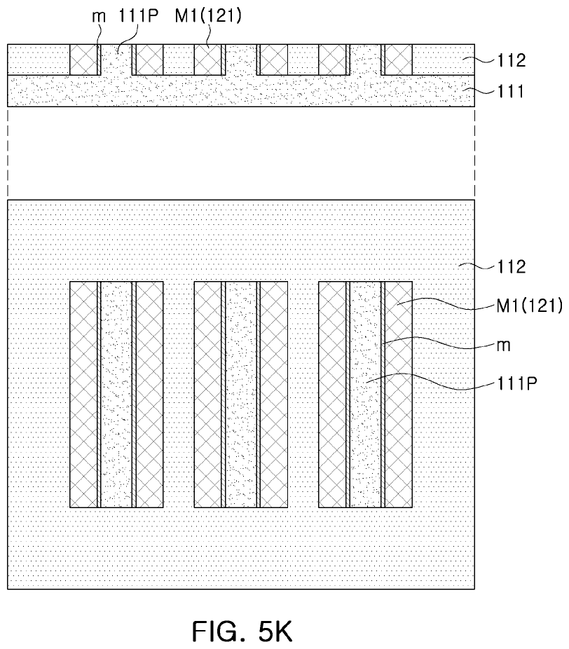

FIGS. 5A to 5K are process diagrams schematically illustrating an example of manufacturing the printed circuit board of FIGS. 3 and 4.

Referring to the drawings, a method of manufacturing a printed circuit board 100A according to an example may include forming a first dry film 220 on a detachable substrate 210; forming a plurality of dry film patterns 221 spaced apart from each other on the detachable substrate 210 by patterning the first dry film 220; forming a seed metal layer m covering each of the plurality of dry film patterns 221 on the detachable substrate 210; forming a first plating layer M1 on the seed metal layer m along the detachable substrate 210 and the plurality of dry film patterns 221; forming a second insulating layer 112 on the first plating layer M1 to cover the first plating layer M1 and to fill a space G1 between side surfaces of the first plating layer M1, facing each other and distant from the seed metal layer; polishing at least a portion of the second insulating layer 112, at least a portion of the first plating layer M1, and at least a portion of the seed metal layer m; removing the plurality of dry film patterns 221 remaining between side surfaces of the seed metal layer m, facing each other and distant from the first plating layer; forming a first insulating layer 111 on the detachable substrate 210 to cover the second insulating layer 112 and the first plating layer M1 and to fill a space G2 between the side surfaces of the seed metal layer m; removing the detachable substrate 210; and polishing at least a portion of the seed metal layer m, at least a portion of the first plating layer M1, and at least a portion of the first insulating layer 111.

In the forming a plurality of dry film patterns 221, if a width of each of the plurality of dry film patterns 221 in cross-sectional view is n, a separation distance between the plurality of dry film patterns 221 in the cross-sectional view may substantially satisfy 3n. Also, in the forming a first plating layer M1, a thickness or a width of the first plating layer M1 in cross-sectional view may substantially satisfy n. For example, even when the first dry film 220 is exposed at a ratio of line/space of about 1:3, as a result, a plurality of first circuit patterns 121 having a ratio of line/space of about 1:1 may be formed to secure a margin of an exposure process.

Unlike conventional SAP, MSAP, ETS, or the like, as described above, a printed circuit board 100A according to an example formed by such a manufacturing method, may be patterned by exposure and development such that a line/space of a dry film for forming a pattern has a ratio of 1:1 or lower, for example, about 1:3. It is possible to overcome a limitation of resolution of exposure equipment, and a separate seed etching process may not be performed. As a result, a microcircuit having a line/space of, for example, approximately 2 μm/2 μm or less may be easily formed. In addition, since a recess step difference and a circuit thickness deviation, which were unnecessarily generated during a seed etching process of the ETS, may not occur, reliability of a product therefrom may be improved.

Hereinafter, a method of manufacturing a printed circuit board 100A according to an example will be described in more detail with reference to the drawings.

Referring to FIG. 5A, a first dry film 220 may be formed on a detachable substrate 210. The detachable substrate 210 may be a copper clad laminate (CCL), but is not limited thereto, and various types of detachable carrier substrates may be used. The detachable substrate 210 may include a detachable core 211 and a detachable layer 212. The detachable core 211 may include an insulating material, and the detachable layer 212 may include metal. As necessary, a releasable layer may be further disposed between the two. The first dry film 220 may include a positive- or negative-type photosensitive insulating material.

Referring to FIG. 5B, a plurality of dry film patterns 221 spaced apart from each other may be formed on the detachable substrate 210 by patterning the first dry film 220. The patterning of the first dry film 220 may use a photolithography process, for example, an exposure and development process. In this case, as described above, if a width of each of the plurality of dry film patterns 221 in cross-sectional view is n, a separation distance between the plurality of dry film patterns 221 in the cross-sectional view may substantially satisfy 3n. For example, a line/space may have a ratio of approximately n/3n, but is not limited thereto.

Referring to FIG. 5C, a seed metal layer m covering each of the plurality of dry film patterns 221 may be formed on the detachable substrate 210. The seed metal layer m may be formed by a sputtering process, but is not limited thereto, and may be formed by electroless plating, for example, as chemical copper, as necessary. The seed metal layer m may be formed along the detachable substrate 210 and the plurality of dry film patterns 221, to have a thin thickness.

Referring to FIG. 5D, a first plating layer M1 may be formed on the seed metal layer m along the detachable substrate 210 and the plurality of dry film patterns 221. The first plating layer M1 may be formed by electrolytic plating, for example, as electrolytic copper. In this case, as described above, a thickness or a width of the first plating layer M1 in cross-sectional view may substantially satisfy n. Therefore, a plurality of first circuit patterns 121 having a ratio of line/space of about 1:1 may be subsequently formed, but are not limited thereto.

Referring to FIG. 5E, portions of the first plating layer M1 disposed on both end portions of each of the plurality of dry film patterns 221 in plan view may be removed. For example, cut etching may be performed. Thereby, it is possible to prevent the first plating layer M1 from being connected on both end portions of each of the plurality of dry film patterns 221. In this process, portions of the seed metal layer m disposed on both end portions of each of the plurality of dry film patterns 221 in plan view may also be removed. A specific process for this will be described later.

Referring to FIG. 5F, a second insulating layer 112 may be formed on the first plating layer M1 to cover the first plating layer M1 and to fill a space G1 between side surfaces of the first plating layer M1, facing each other and distant from the seed metal layer. The second insulating layer 112 may be formed by stacking uncured films and then curing them, but is not limited thereto. The second insulating layer 112 may entirely cover a surface of the first plating layer M1.

Referring to FIG. 5G, on a side, opposite to a side on which the detachable substrate 210 is disposed, at least a portion of the second insulating layer 112, at least a portion of the first plating layer M1, and at least a portion of the seed metal layer m may be polished. For example, the polishing may be performed until at least the plurality of dry film patterns 221 are exposed. As necessary, each of the plurality of dry film patterns 221 may be partially polished. As the polishing process, chemical mechanical polishing (CMP) may be used, but is not limited thereto, and other mechanical and/or chemical planarization processes may be used.

Referring to FIG. 5H, the plurality of dry film patterns 221 remaining between side surfaces of the seed metal layer m, facing each other and distant from the first plating layer, may be removed. The plurality of dry film patterns 221 may be removed using a known peeling solution, but is not limited thereto, and mechanical peeling may be performed.

Referring to FIG. 5I, a first insulating layer 111 on the detachable substrate 210 to cover the second insulating layer 112 and the first plating layer M1 and to fill a space G2 between the side surfaces of the seed metal layer m, may be formed. The first insulating layer 111 may be formed by stacking uncured films and then curing them, but is not limited thereto. The first insulating layer 111 may entirely cover an exposed surface of the second insulating layer 112, an exposed surface of the first plating layer M1, and an exposed surface of the seed metal layer m.

Referring to 5J, the detachable substrate 210 may be removed. For example, the detachable substrate 210 may be removed by separating the detachable core 211 from the detachable layer 212. The remaining detachable layer 212 may be removed first, or may be removed in a second polishing operation to be described later.

Referring to FIG. 5K, on a side from which the detachable substrate 210 is removed, at least a portion of the seed metal layer m, at least a portion of the first plating layer M1, and at least a portion of the first insulating layer 111 may be polished. For example, the polishing may be performed until at least the second insulating layer 112 is exposed. As necessary, a portion of the second insulating layer 112 may also be polished. In addition, the remaining detachable layer 212 may also be polished. CMP may be used as the polishing process, but is not limited thereto, and other mechanical and/or chemical planarization processes may be used. After the polishing, a plurality of first circuit patterns 121 buried in the insulating materials (111, 111P, and 112), respectively, may be formed.

Since the printed circuit board 100A according to the above-described example may be formed by a series of processes, and others may be substantially the same as those described in a printed circuit board 100A according to the above-described example, overlapping description thereof will be omitted.

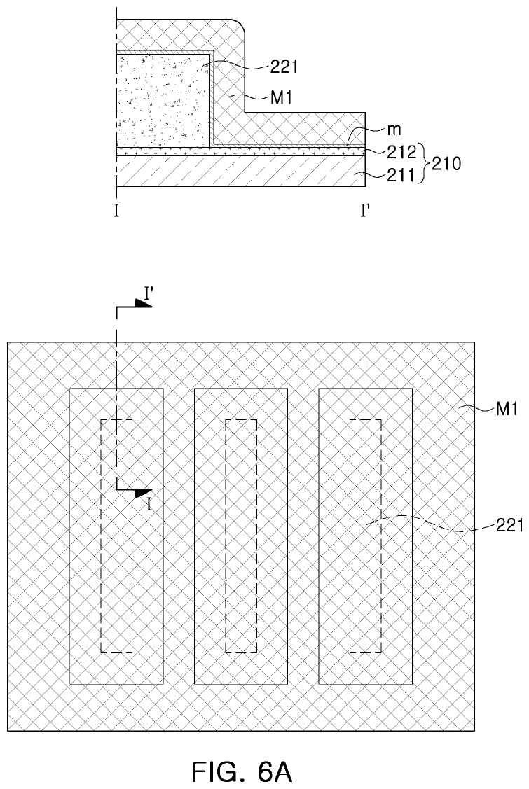

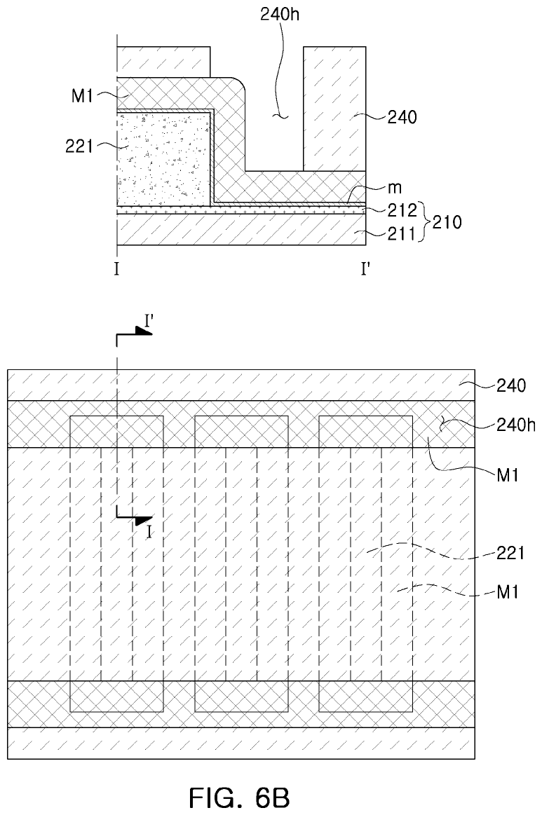

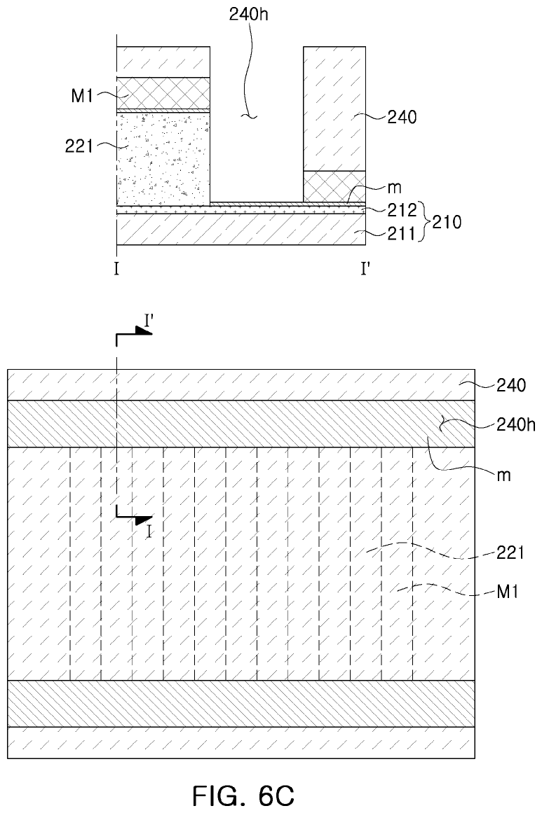

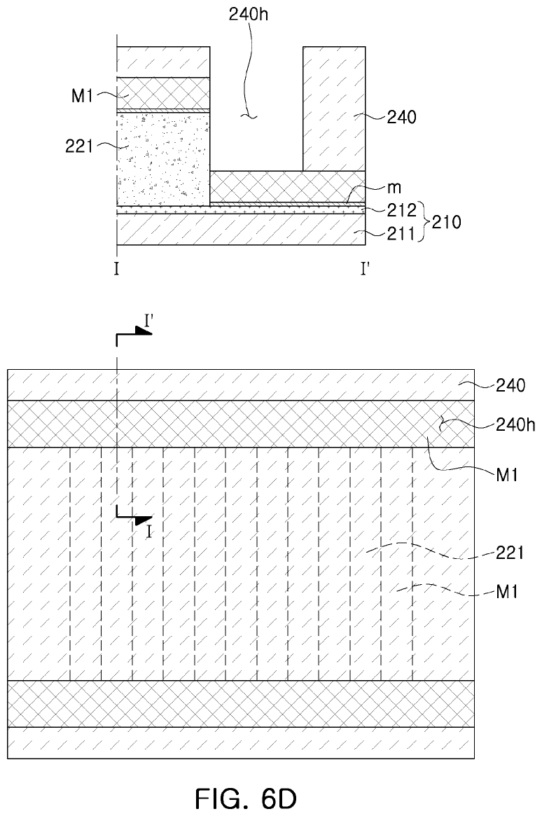

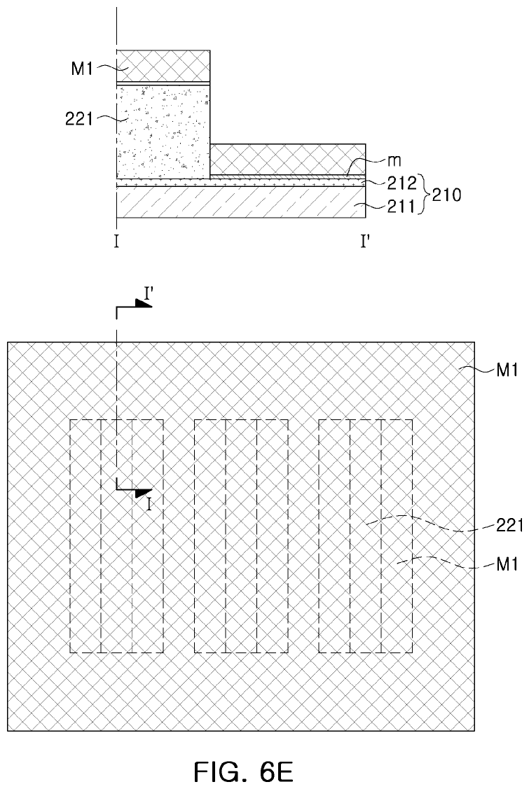

FIGS. 6A to 6E are process diagrams schematically illustrating an example of the cut etching of FIG. 5E.

Referring to FIG. 6A, as described above with reference to FIGS. 5A to 5D, a first plating layer M1 may be formed on a seed metal layer m along a detachable substrate 210 and a plurality of dry film patterns 221. In this case, the first plating layer M1 and the seed metal layer m may be connected on both end portions of each of the plurality of dry film patterns 221.

Referring to FIG. 6B, a third dry film 240 may be formed on the first plating layer M1, and may be then patterned to form an opening 240h exposing the first plating layer M1 disposed on both end portions of each of the plurality of dry film patterns 221. The third dry film 240 may include a positive- or negative-type photosensitive insulating material. The opening 240h may be formed by a photolithography process, for example, an exposure and development process.

Referring to FIG. 6C, a continuous portion of the first plating layer M1 exposed through the opening 240h may be removed by cut etching. As the cut etching, known wet or dry etching may be used. In this case, a continuous portion of the seed metal layer m may also be removed.

Referring to FIG. 6D, a first plating layer M1 having a thin thickness may be additionally formed on the seed metal layer m exposed through the opening 240h. The additionally formed first plating layer M1 may be formed by electrolytic plating, for example, as electrolytic copper. In this case, the additionally formed first plating layer M1 may be disconnected from the first plating layer M1 disposed on the plurality of dry film patterns 221, on sidewalls of both end portions of each of the plurality of dry film patterns 221.

Referring to FIG. 6E, the third dry film 240 may be removed. The third dry film 240 may be removed using a known peeling solution, but is not limited thereto, and mechanical peeling may be performed.

The above-described cut etching may proceed by a series of processes, and thereby, it is possible to prevent the first plating layer M1 and/or the seed metal layer m from being connected at both end portions of each of the plurality of dry film patterns 221.

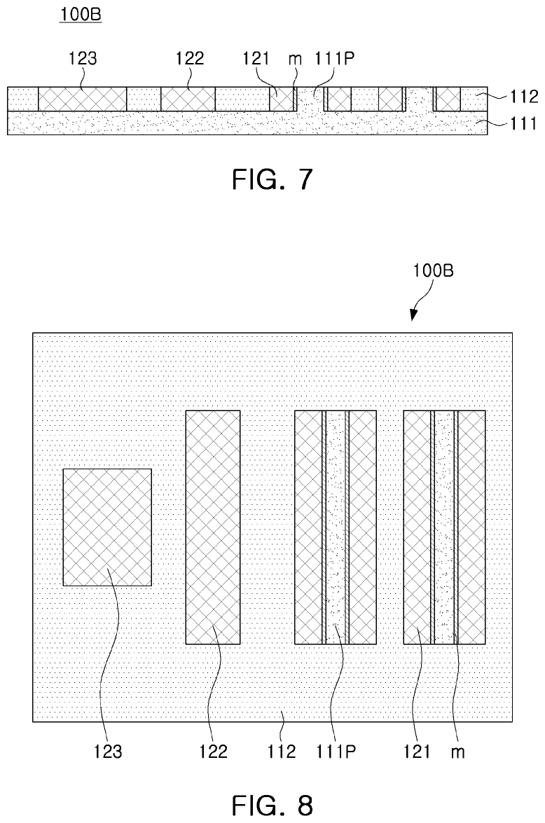

FIG. 7 is a schematic cross-sectional view of another example of a printed circuit board.

FIG. 8 is a plan view illustrating a schematic plan view of the printed circuit board of FIG. 7.

Referring to the drawings, a printed circuit board 100B according to another example may further include a second circuit pattern 122 and a pad pattern 123, respectively disposed on a first insulating layer 111, as compared to the printed circuit board 100A according to the above-described example. The second circuit pattern 122 may be a general circuit, rather than a microcircuit, and thus may have a line width, wider than a line width of each of the plurality of first circuit patterns 121 in cross-sectional view. The pad pattern 123 may be a pattern in which vias for interlayer connection are connected, and therefore, a width of the pad pattern 123 in cross-sectional view may be wider than a respective line width of a plurality of first circuit patterns 121 and/or the line width of the second circuit pattern 122.

The first insulating layer 111 may be spaced apart from both side surfaces of the second circuit pattern 122 and both side surfaces of the pad pattern 123, and the second insulating layer 112 may cover both side surfaces of the second circuit pattern 122 and both side surfaces of the pad pattern 123.

An upper surface of the second circuit pattern 122 and an upper surface of the pad pattern 123 may be substantially coplanar with an upper surface of each of the plurality of first circuit patterns 121, an upper surface of a second insulating layer 112, and an upper surface of an insulator 111P. The upper surface and each other may. In addition, a lower surface of each of the second circuit patterns 122 and a lower surface of the pad patterns 123 may be substantially coplanar with a lower surface of each of the plurality of first circuit patterns 121 and a lower surface of the second insulating layer 112.

A seed metal layer m may not be disposed on both side surfaces and upper and lower surfaces of the second circuit pattern 122, and both side surfaces and upper and lower surfaces of the pad pattern 123, respectively.

A printed circuit board 100B according to another example of such a structure may be formed by a new process to be described later, and in this case, may include a microcircuit and a general circuit, and more diverse designs are possible. In addition, the printed circuit board 100B may include a pad pattern, and, thus, may be more easily applied to a multilayer substrate.

Hereinafter, components of a printed circuit board 100B according to another example will be described in more detail with reference to the drawings.

The second circuit pattern 122 may include a metal. The metal may include copper (Cu), aluminum (Al), silver (Ag), tin (Sn), gold (Au), nickel (Ni), lead (Pb), titanium (Ti), and/or alloys thereof, or the like. Preferably, copper (Cu) may be included, but is not limited thereto. The second circuit pattern 122 may perform various functions according to a design. For example, a signal pattern, a power pattern, a ground pattern, or the like may be included. A plurality of second circuit patterns 122 may exist, and each of the plurality of second circuit patterns 122 may have various shapes such as a line, a plane, or the like. The second circuit pattern 122 may include an electrolytic plating layer (or electrolytic copper).

The pad pattern 123 may include a metal. The metal may include copper (Cu), aluminum (Al), silver (Ag), tin (Sn), gold (Au), nickel (Ni), lead (Pb), titanium (Ti), and/or alloys thereof, or the like. Preferably, copper (Cu) may be included, but is not limited thereto. The pad pattern 123 may perform various functions according to a design. For example, a pad pattern for signals, a pad pattern for power, a pad pattern for ground, or the like may be included. A plurality of pad patterns 123 may exist, and may be electrically connected to at least one of the plurality of first circuit patterns 121 or at least one of the plurality of second circuit patterns 122. The pad pattern 123 may include an electrolytic plating layer (or electrolytic copper).

Others may be substantially the same as those described in the printed circuit board 100A according to the above-described example, and thus, overlapping description thereof will be omitted.

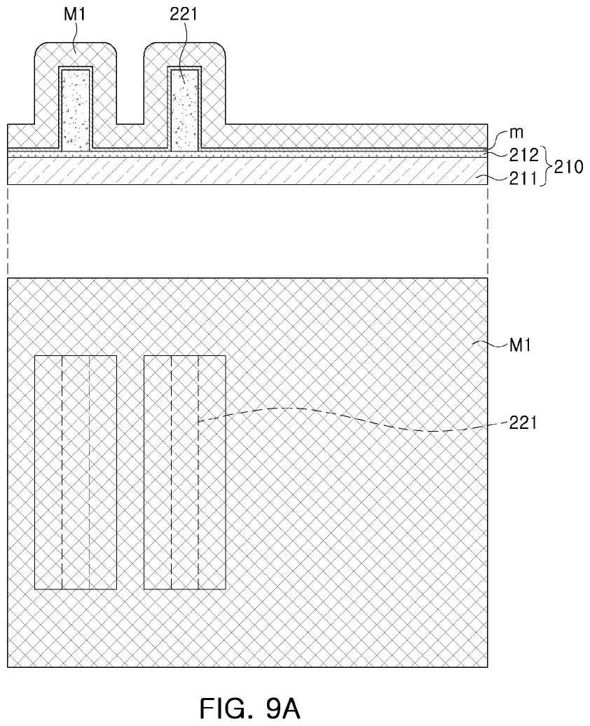

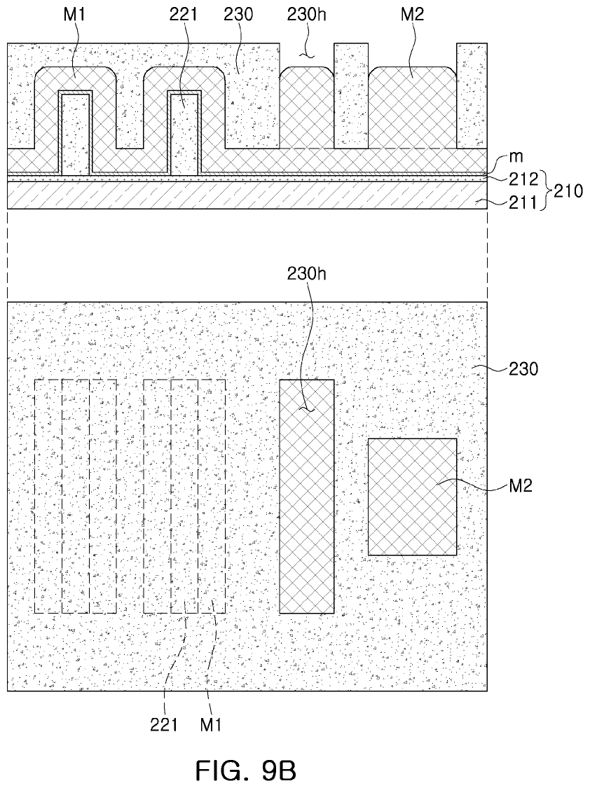

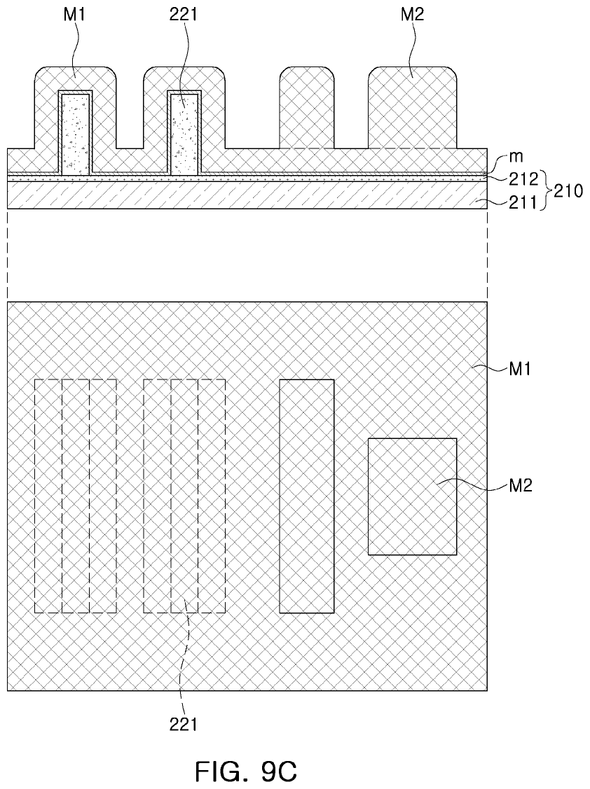

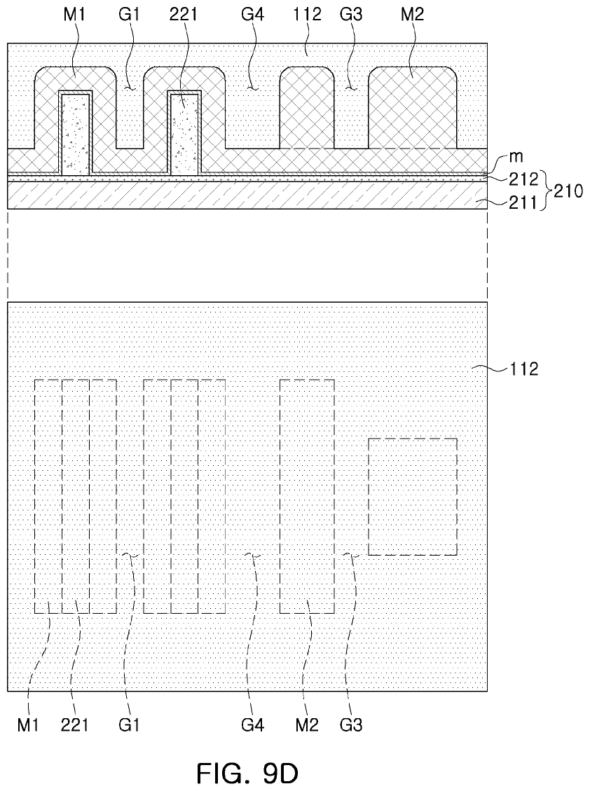

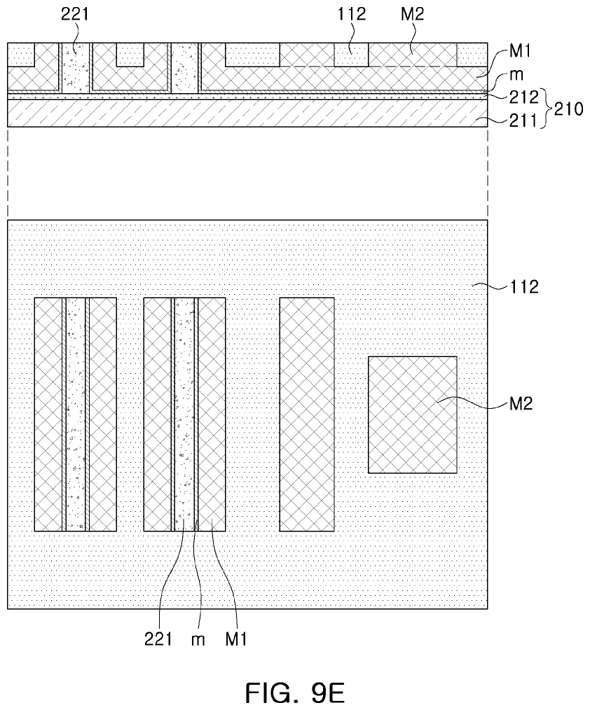

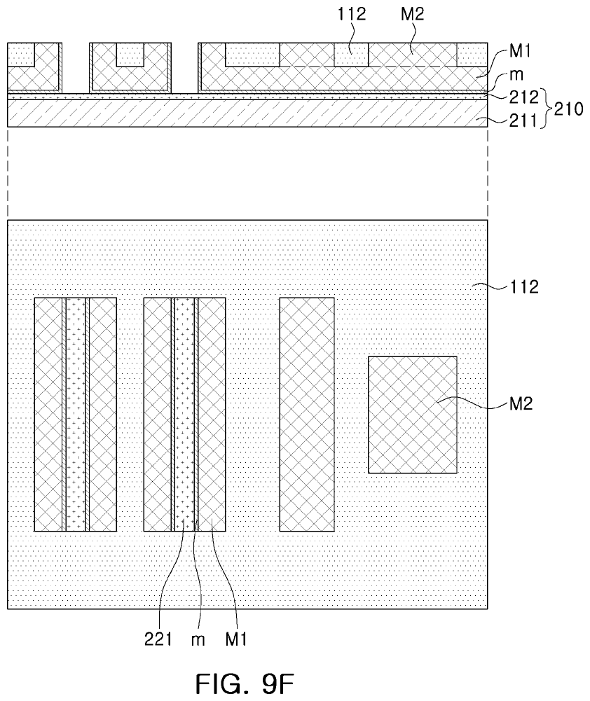

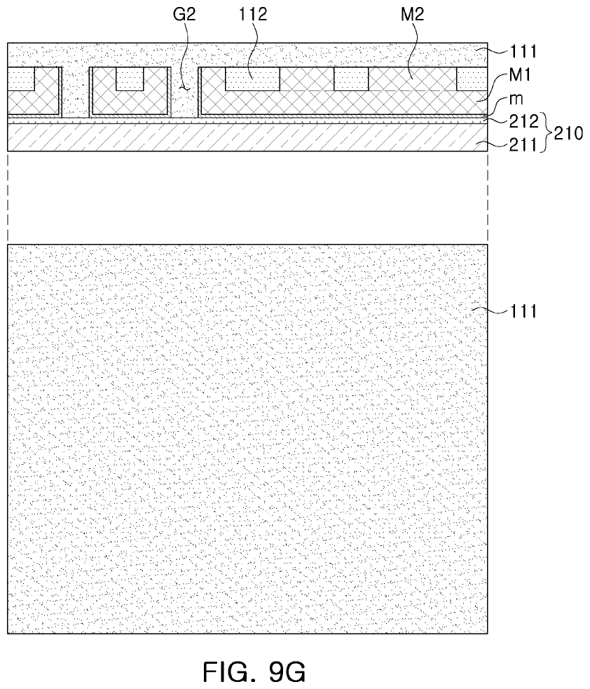

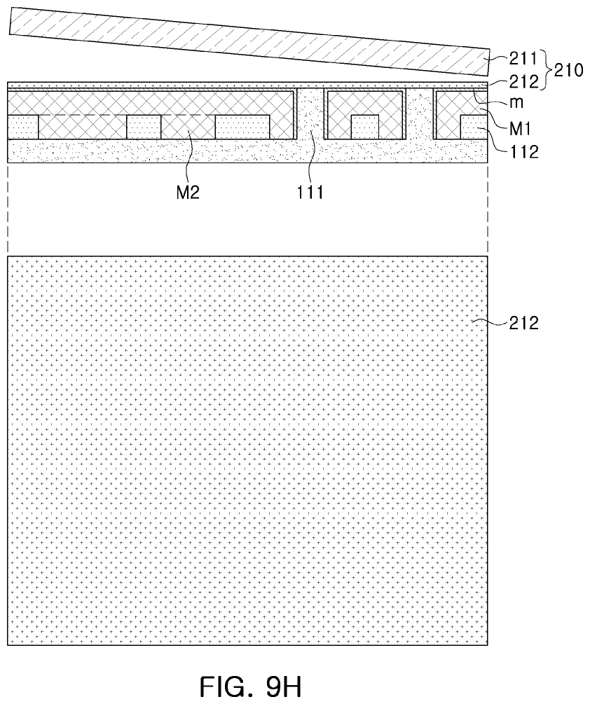

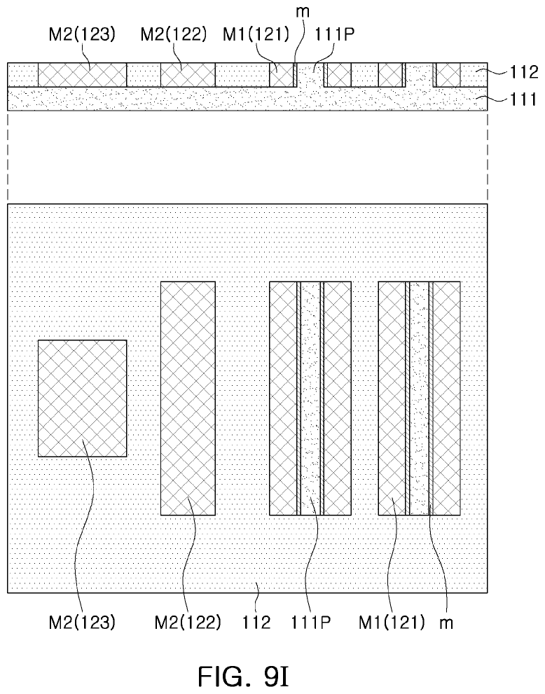

FIGS. 9A to 9I are process diagrams schematically illustrating an example of manufacturing the printed circuit board of FIGS. 7 and 8.

Referring to the drawings, a method of manufacturing a printed circuit board 100B according to another example may further include, after forming a first plating layer M1, forming a second dry film 230 on the first plating layer M1; forming a plurality of opening patterns 230h exposing the first plating layer M1 by patterning the second dry film 230; forming second plating layers M2 in the plurality of opening patterns 230h; and removing the second dry film 230, as compared to the manufacturing method of the printed circuit board 100A according to the above-described example.

In forming a second insulating layer 112, the second insulating layer 112 may further cover the second plating layers M2, and may further fill a space G3 between the second plating layers M2, and a space G4 between the first plating layer M1 and each of the second plating layers M2. In addition, in polishing at least a portion of the second insulating layer 112, at least a portion of the first plating layer M1, and at least a portion of the seed metal layer m, at least a portion of each of the second plating layers M2 may be further polished. Also, in forming a first plating layer 111, the first insulating layer 111 may further cover the second plating layers M2.

A printed circuit board 100B according to another example formed by this manufacturing method may include a microcircuit and a general circuit, may include a pad pattern, and, thus, more diverse designs are possible, and may be more easily applied to a multilayer substrate.

Hereinafter, a method of manufacturing a printed circuit board 100B according to another example will be described in more detail with reference to the drawings.

Referring to FIG. 9A, a plurality of dry film patterns 221, a seed metal layer m, and a first plating layer M1 may be formed on a detachable substrate 210, by substantially the same process as in FIGS. 5A to 5E.

Referring to FIG. 9B, a second dry film 230 may be formed on the first plating layer M1, the second dry film 230 may be patterned to form a plurality of opening patterns 230h exposing the first plating layer M1, and second plating layers M2 may be formed in the plurality of opening patterns 230h. The second dry film 230 may include a positive- or negative-type photosensitive insulating material, and the plurality of opening patterns 230h may be formed by a photolithography process, for example, an exposure and development process. The second plating layer M2 may be formed by electrolytic plating, for example, as electrolytic copper.

Referring to FIG. 9C, the second dry film 230 may be removed. The second dry film 230 may be removed using a known peeling solution, but is not limited thereto, and mechanical peeling may be performed.

Referring to FIG. 9D, a second insulating layer 112 covering the first and second plating layers M1 and M2, and filling a space G1 between side surfaces of the first plating layer M1, facing each other and distant from the seed metal layer m, a space G3 between the second plating layers M2, and a space G4 between the first plating layer M1 and each of the second plating layers M2, may be formed on the first and second plating layers M1 and M2. The second insulating layer 112 may be formed by stacking uncured films and then curing them, but is not limited thereto. The second insulating layer 112 may entirely cover a surface of the first plating layer M1 and a surface of each of the second plating layers M2.

Referring to FIG. 9E, on a side, opposite to a side on which the detachable substrate 210 is disposed, at least a portion of the second insulating layer 112, at least a portion of the first plating layer M1, at least a portion of each of the second plating layer M2, and at least a portion of the seed metal layer m may be polished. For example, the polishing may be performed until at least the plurality of dry film patterns 221 are exposed. As necessary, each of the plurality of dry film patterns 221 may be partially polished. As the polishing process, CMP may be used, but is not limited thereto, and other mechanical and/or chemical planarization processes may be used.

Referring to FIG. 9F, the plurality of dry film patterns 221 remaining between side surfaces of the seed metal layer m, facing each other and distant from the first plating layer, may be removed. The plurality of dry film patterns 221 may be removed using a known peeling solution, but is not limited thereto, and mechanical peeling may be performed.

Referring to FIG. 9G, a first insulating layer 111 on the detachable substrate 210 to cover the second insulating layer 112, the first plating layer M1, and the second plating layers M2, and to fill a space G2 between the side surfaces of the seed metal layer m, may be formed. The first insulating layer 111 may be formed by stacking uncured films and then curing them, but is not limited thereto. The first insulating layer 111 may entirely cover an exposed surface of the second insulating layer 112, an exposed surface of the first plating layer M1, exposed surfaces of the second plating layers M2, and an exposed surface of the seed metal layer m.

Referring to FIG. 9H, the detachable substrate 210 may be removed. For example, the detachable substrate 210 may be removed by separating a detachable core 211 from a detachable layer 212. The remaining detachable layer 212 may be removed first, or may be removed in a second polishing operation to be described later.

Referring to FIG. 9I, on a side from which the detachable substrate 210 is removed, at least a portion of the seed metal layer m, at least a portion of the first plating layer M1, and at least a portion of the first insulating layer 111 may be polished. For example, the polishing may be performed until at least the second insulating layer 112 and each of the second plating layers M2 are exposed. As necessary, a portion of the second insulating layer 112 and a portion of each of the second plating layers M2 may also be polished. In addition, the remaining detachable layer 212 may also be polished. CMP may be used as the polishing process, but is not limited thereto, and other mechanical and/or chemical planarization processes may be used. After the polishing, a plurality of first circuit patterns 121 and a plurality of second circuit patterns 122, and a plurality of pad patterns 123, buried in the insulating materials (111, 111P, and 112), respectively, may be formed.

Since the printed circuit board 100B according to another example described above may be formed by a series of processes, and others may be substantially the same as those described in above-described printed circuit boards 100A and 100B and a manufacturing method of the above-described printed circuit board 100A, overlapping description thereof will be omitted.

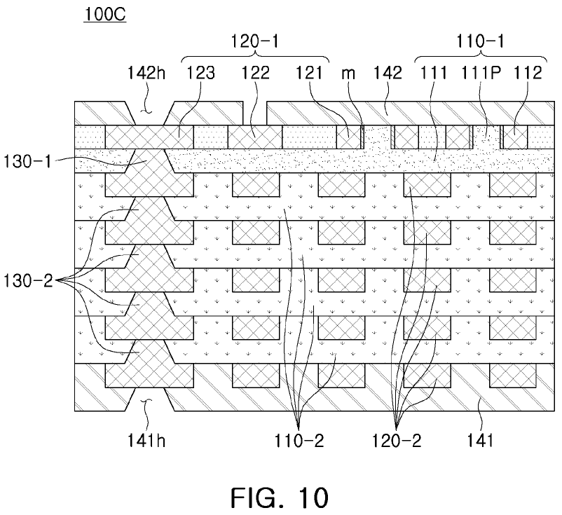

FIG. 10 is a schematic cross-sectional view of another example of a printed circuit board.

Referring to the drawings, a printed circuit board 100C according to another example may include a plurality of build-up insulating layers 110-1 and 110-2, a plurality of build-up wiring layers 120-1 and 120-2, and a plurality of build-up via layers 130-1 and 130-2. At least one (e.g., 110-1) of the plurality of build-up insulating layers 110-1 and 110-2 may include a first insulating layer 111, a second insulating layer 112, and an insulator 111P, as in the printed circuit board 100B according to another example described above, and at least one (e.g., 120-1) of the plurality of build-up wiring layers 120-1 and 120-2 may include a plurality of first circuit patterns 121, a plurality of second circuit patterns 122, and a plurality of pad patterns 123, in plural, as in the printed circuit board 100B according to another example described above. A build-up insulating layer 110-1 including the first insulating layer 111, the second insulating layer 112, and the insulator 111P may be disposed as an outermost build-up insulating layer among the plurality of build-up insulating layers 110-1 and 110-2. A build-up wiring layer 120-1 including the plurality of first circuit patterns 121, the plurality of second circuit patterns 122, and the plurality of pad patterns 123 may be disposed as an outermost build-up wiring layer among the plurality of build-up wiring layers 120-1 and 120-1. For example, a structure of the printed circuit board 100B according to another example described above may be applied as an outermost layer in a structure of a multilayer coreless substrate of a printed circuit board 100C according to another example.

A printed circuit board 100C according to another example may further include first and second resist layers 141 and 142 disposed on both sides of the plurality of build-up insulating layers 110-1 and 110-2, respectively. The first and second resist layers 141 and 142 may have first and second openings 141h and 142h at least partially exposing the outermost build-up wiring layer 120-2 and the outermost build-up wiring layer 120-1, among the plurality of build-up wiring layers 120-1 and 120-2, respectively.

In the build-up wiring layer 120-1 including the plurality of first circuit patterns 121, the plurality of second circuit patterns 122, and the plurality of pad patterns 123, a seed metal layer m may be disposed on one side surface of each of the plurality of first circuit patterns 121, and may not be disposed on upper and lower surfaces of each of the plurality of first circuit patterns 121, each of the plurality of second circuit patterns 122, and each of the plurality of pad patterns 123. In a build-up wiring layer 120-2 other than the above-described build-up wiring layer 120-1, among the plurality of build-up wiring layers 120-1 and 120-2, a seed metal layer (not illustrated) may be disposed on an upper or lower surface of each circuit pattern. As described above, the plurality of build-up wiring layers 120-1 and 120-2 may have different manufacturing processes, as will be described later, and, thus, may have different arrangements of seed metal layers.

Hereinafter, components of a printed circuit board 100C according to another example will be described in more detail with reference to the drawings.

Each of the plurality of build-up insulating layers 110-1 and 110-2 may include an insulating material. The insulating material may include a thermosetting resin such as an epoxy resin, a thermoplastic resin such as polyimide, or a material including an inorganic filler, an organic filler, and/or glass fiber (glass cloth, glass fabric) together with a resin. For example, the insulating material may be a non-photosensitive insulating material such as Ajinomoto Build-up Film (ABF), a prepreg (PPG), or the like, but is not limited thereto, and other polymer materials may be used. In addition, the insulating material may be a photosensitive insulating material such as a photoimageable dielectric (PID) or the like.

The outermost build-up insulating layer 110-1 among the plurality of build-up insulating layers 110-1 and 110-2 may include a plurality of insulating layers 111, a plurality of insulating layers 112, and a plurality of insulators 111P. The plurality of insulating layers 111 and 112 may include insulating materials, substantially identical to each other, or may include insulating materials, different from each other, and in either case, an interlayer boundary may exist. The insulating layer 111 and the insulator 111P may include substantially the same insulating material, and may be integrated without a boundary. Among the plurality of build-up insulating layers 110-1 and 110-2, remaining build-up insulating layers 110-2 may include substantially the same insulating material, but may include different insulating materials, as necessary.

Each of the plurality of build-up wiring layers 120-1 and 120-2 may include a metal. The metal may include copper (Cu), aluminum (Al), silver (Ag), tin (Sn), gold (Au), nickel (Ni), lead (Pb), titanium (Ti), and/or alloys thereof, or the like. Preferably, copper (Cu) may be included, but is not limited thereto. Each of the plurality of build-up wiring layers 120-1 and 120-2 may perform various functions according to a design. For example, a signal pattern, a power pattern, a ground pattern, or the like may be included. Each of these patterns may have various shapes such as a line, a plane, a pad, or the like.

The outermost build-up wiring layer 120-1 among the plurality of build-up wiring layers 120-1 and 120-2 may be disposed in the outermost build-up insulating layer 110-1 among the plurality of build-up insulating layers 110-1 and 110-2. Remaining build-up wiring layers 120-2 among the plurality of build-up wiring layers 120-1 and 120-2 may be disposed on or in remaining build-up insulating layers 110-2 among the plurality of build-up insulating layers 110-1 and 110-2, respectively. Among the plurality of build-up wiring layers 120-1 and 120-2, the outermost build-up wiring layer 120-1 may include an electrolytic plating layer (or electrolytic copper), and a sputtering layer and/or an electroless plating layer (or chemical copper) may be included in a portion of a side surface of only some microcircuits thereof as a seed metal layer. The remaining build-up wiring layer 120-2 may include an electroless plating layer (or chemical copper) and an electrolytic plating layer (or electrolytic copper). Alternatively, the remaining build-up wiring layer 120-2 may include a metal foil (or copper foil) and an electrolytic plating layer (or electrolytic copper). Alternatively, the remaining build-up wiring layer 120-2 may include the metal foil (or copper foil), an electroless plating layer (or chemical copper), and the electrolytic plating layer (or electrolytic copper). The remaining build-up wiring layer 120-2 may include a sputtering layer, instead of the electroless plating layer (or chemical copper), and both may be included, as necessary.

Each of the plurality of build-up via layers 130-1 and 130-2 may include a metal. The metal may include copper (Cu), aluminum (Al), silver (Ag), tin (Sn), gold (Au), nickel (Ni), lead (Pb), titanium (Ti), and/or alloys thereof, or the like. Preferably, copper (Cu) may be included, but is not limited thereto. Each of the plurality of build-up via layers 130-1 and 130-2 may include a filed via filling a via hole, but may also include a conformal via disposed along a wall surface of the via hole. The vias respectively included in the plurality of build-up via layers 130-1 and 130-2 may perform various functions according to a design. For example, a ground via, a power via, a signal via, or the like may be included. The vias respectively included in the plurality of build-up via layers 130-1 and 130-2 may have a tapered shape in the same direction as each other in cross-sectional view.

An outermost build-up via layer 130-1 among the plurality of build-up via layers 130-1 and 130-2 may pass through the outermost build-up insulating layer 110-1 among the plurality of build-up insulating layers 110-1 and 110-2, and may be connected to the outermost build-up wiring layer 120-1 among the plurality of build-up wiring layers 120-1 and 120-2. Remaining build-up via layer 130-2 among the plurality of build-up via layers 130-1 and 130-2 may pass through remaining build-up insulating layer 110-2 among the plurality of build-up insulating layers 110-1 and 110-2, and may be connected to remaining build-up wiring layer 120-2 among the plurality of build-up wiring layers 120-1 and 120-2. Each of the plurality of build-up via layers 130-1 and 130-2 may include an electroless plating layer (or chemical copper) and an electrolytic plating layer (or electrolytic copper). A sputtering layer may be included, instead of the electroless plating layer (or chemical copper), and both may be included, as necessary.

The first and second resist layers 141 and 142 may include a liquid- or film-type solder resist, but is not limited thereto, and other types of insulating materials may be used. A surface treatment layer may be formed on a pattern exposed through the first opening 141h and/or the second opening 142h, as necessary. Alternatively, a metal bump may be formed on the pattern exposed through the first opening 141h and/or the second opening 142h. The second resist layer 142 may be in contact with the second insulating layer 112 and the insulator 111P, respectively.

Since others may be substantially the same as those described in the above-described printed circuit boards 100A and 100B, overlapping description thereof will be omitted.

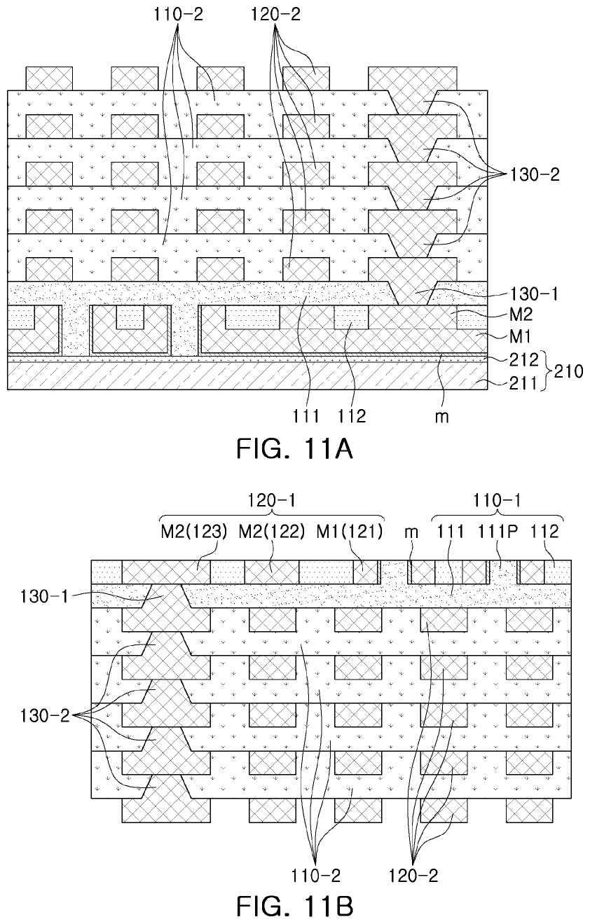

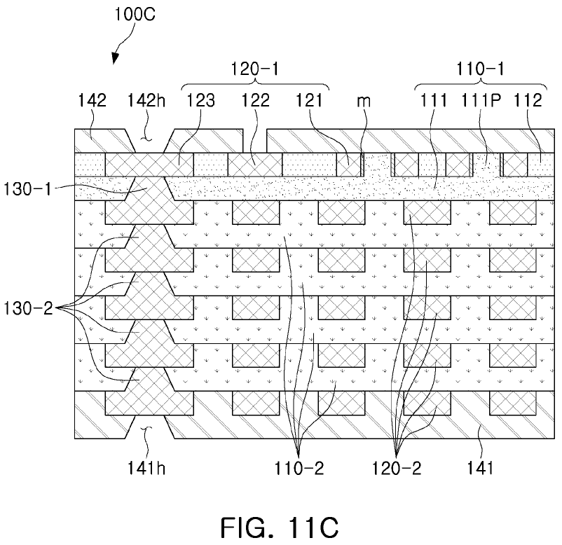

FIGS. 11A to 11C are process diagrams schematically illustrating an example of manufacturing the printed circuit board of FIG. 10.

Referring to the drawings, a method of manufacturing a printed circuit board 100C according to another example may further include, after forming a first insulating layer 111, forming a plurality of build-up insulating layers 110-2, a plurality of build-up wiring layers 120-2, and a plurality of build-up via layers 130-1 and 130-2, as compared to the manufacturing method of the printed circuit board 100B according to the above-described example. For example, in a method of manufacturing a printed circuit board 100C according to another example, a multilayer coreless substrate may be formed, before a detaching operation, in the manufacturing method of the printed circuit board 100B according to another example described above. Therefore, a structure of the printed circuit board 100B according to another example described above may be applied as an outermost layer in a structure of the multilayer coreless substrate of the printed circuit board 100C according to another example.

A method of manufacturing a printed circuit board 100C according to another example may further include, after polishing at least a portion of a seed metal layer m, at least a portion of a first plating layer M1, and at least a portion of a first insulating layer 111, forming first and second resist layers 141 and 142 on both sides of build-up insulating layers 110-1 and 110-2, respectively. In addition, the method may further include forming first and second openings 141h and 142h at least partially exposing outermost build-up wiring layers 120-2 and 120-1 disposed on both sides of a plurality of build-up wiring layers 120-1 and 120-2, to the first and second resist layers 141 and 142, respectively.

Hereinafter, a method of manufacturing a printed circuit board 100C according to another example will be described in more detail with reference to the drawings.

Referring to FIG. 11A, first and second insulating layers 111 and 112, first and second plating layers M1 and M2, and a seed metal layer m may be formed on a detachable substrate 210 by substantially the same process as FIGS. 9A to 9G described above. Next, a plurality of build-up insulating layers 110-2, a plurality of build-up wiring layers 120-2, and a plurality of build-up via layers 130-1 and 130-2 may be formed by a build-up process. The plurality of build-up insulating layers 110-2 may be formed by stacking uncured insulating materials and then curing them, and the plurality of build-up wiring layers 120-2 and the plurality of build-up via layers 130-1 and 130-2 may be formed by a plating process using SAP, MSAP, tenting, or the like, after processing via holes in the first insulating layer 111 and the plurality of build-up insulating layers 110-2.

Referring to FIG. 11B, a detachable substrate 210 may be removed. For example, the detachable substrate 210 may be removed by separating a detachable core 211 from a detachable layer 212. The remaining detachable layer 212 may be removed first, or may be removed in a second polishing operation to be described later. Next, on a side from which the detachable substrate 210 is removed, at least a portion of the seed metal layer m, at least a portion of the first plating layer M1, and at least a portion of the first insulating layer 111 may be polished. For example, the polishing may be performed until at least the second insulating layer 112 and the second plating layer M2 are exposed. As necessary, a portion of the second insulating layer 112 and a portion of the second plating layer M2 may also be polished. In addition, the remaining detachable layer 212 may also be polished. CMP may be used as the polishing process, but is not limited thereto, and other mechanical and/or chemical planarization processes may be used. After the polishing, a plurality of first circuit patterns 121, a plurality of second circuit patterns 122, and a plurality of pad patterns 123, buried in the insulating materials (111, 111P, and 112), respectively, may be formed. An outermost build-up insulating layer 110-1 among the plurality of build-up insulating layers 110-1 and 110-2 may include the first and second insulating layers 111 and 112. An outermost build-up wiring layer 120-1 among the plurality of build-up wiring layers 120-1 and 120-2 may include the plurality of first circuit patterns 121, the plurality of second circuit patterns 122, and the plurality of pad patterns 123.

Referring to FIG. 11C, first and second resist layers 141 and 142 may be formed on both sides of the plurality of build-up insulating layers 110-1 and 110-2, respectively. In addition, first and second openings 141h and 142h at least partially exposing the outermost build-up wiring layer 120-2 and the outermost build-up wiring layer 120-1, among the plurality of build-up wiring layers 120-1 and 120-2, may be formed in the first and second resist layers 141 and 142, respectively. A surface treatment layer may be formed on a pattern exposed through the first opening 141h and/or the second opening 142h, as necessary. Alternatively, a metal bump may be formed on the pattern exposed through the first opening 141h and/or the second opening 142h.

Since a printed circuit board 100C according to another example described above by a series of processes may be formed, and others may be substantially the same as those described in above-described printed circuit boards 100A, 100B, and 100C, and manufacturing methods of the printed circuit boards 100A and 100B described above, overlapping description thereof will be omitted.

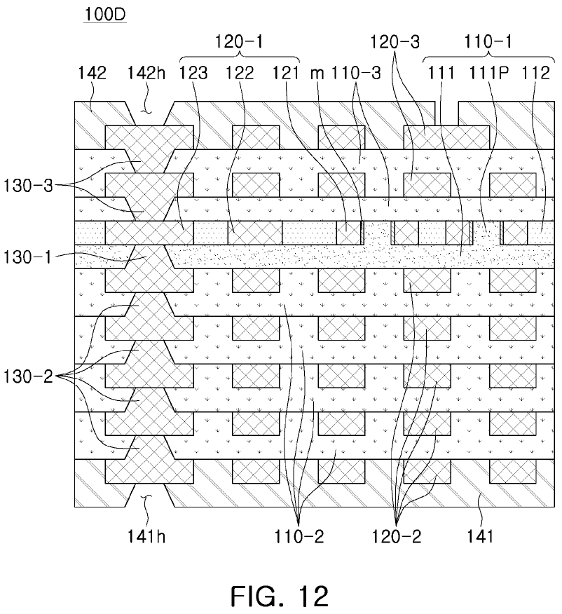

FIG. 12 is a schematic cross-sectional view of another example of a printed circuit board.

Referring to the drawings, a printed circuit board 100D according to another example may include a plurality of build-up insulating layers 110-1, 110-2, and 110-3, a plurality of build-up wiring layers 120-1, 120-2, and 120-3, and a plurality of build-up via layers 130-1, 130-2, and 130-3. At least one (e.g., 110-1) of the plurality of build-up insulating layers 110-1, 110-2, and 110-3 may include a first insulating layer 111, a second insulating layer 112, and an insulator 111P, as in the printed circuit board 100B according to another example described above, and at least one (e.g., 120-1) of the plurality of build-up wiring layers 120-1, 120-2, and 120-3 may include a plurality of first circuit patterns 121, a plurality of second circuit patterns 122, and a plurality of pad patterns 123, in plural, as in the printed circuit board 100B according to another example described above. A build-up insulating layer 110-1 including the first and second insulating layers 111 and 112 and the insulator 111P may be disposed as an inner build-up insulating layer among the plurality of build-up insulating layers 110-1, 110-2, and 110-3. A build-up wiring layer 120-1 including the plurality of first circuit patterns 121, the plurality of second circuit patterns 122, and the plurality of pad patterns 123 may be disposed as an inner build-up wiring layer among the plurality of build-up wiring layers 120-1, 120-2, and 120-3. For example, a structure of the printed circuit board 100B according to another example described above may be applied as an inner layer in a structure of a multilayer coreless substrate of a printed circuit board 100D according to another example.

A printed circuit board 100D according to another example may further include first and second resist layers 141 and 142 disposed on both sides of the plurality of build-up insulating layers 110-1, 110-2, and 110-3, respectively. The first and second resist layers 141 and 142 may have first and second openings 141h and 142h at least partially exposing the outermost build-up wiring layer 120-2 and the outermost build-up wiring layer 120-3, among the plurality of build-up wiring layers 120-1, 120-2, and 120-3, respectively.

In the build-up wiring layer 120-1 including the plurality of first circuit patterns 121, the plurality of second circuit patterns 122, and the plurality of pad patterns 123, a seed metal layer m may be disposed on one side surface of each of the plurality of first circuit patterns 121, and may not be disposed on upper and lower surfaces of each of the plurality of first circuit patterns 121, each of the plurality of second circuit patterns 122, and each of the plurality of pad patterns 123. In build-up wiring layers 120-2 and 120-3 other than the above-described build-up wiring layer 120-1, among the plurality of build-up wiring layers 120-1, 120-2, and 120-3, a seed metal layer (not illustrated) may be disposed on an upper or lower surface of each circuit pattern. As described above, the plurality of build-up wiring layers 120-1, 120-2, and 120-3 may have different manufacturing processes, as will be described later, and, thus, may have different arrangements of seed metal layers.

Hereinafter, components of a printed circuit board 100D according to another example will be described in more detail with reference to the drawings.

Each of the plurality of build-up insulating layers 110-1, 110-2, and 110-3 may include an insulating material. The insulating material may include a thermosetting resin such as an epoxy resin, a thermoplastic resin such as polyimide, or a material including an inorganic filler, an organic filler, and/or glass fiber (glass cloth, glass fabric) together with a resin. For example, the insulating material may be a non-photosensitive insulating material such as Ajinomoto Build-up Film (ABF), a prepreg (PPG), or the like, but is not limited thereto, and other polymer materials may be used. In addition, the insulating material may be a photosensitive insulating material such as a photoimageable dielectric (PID) or the like.

The inner build-up insulating layer 110-1 among the plurality of build-up insulating layers 110-1, 110-2, and 110-3 may include a plurality of insulating layers 111, a plurality of insulating layers 112, and a plurality of insulators 111P. The plurality of insulating layers 111 and 112 may include insulating materials, substantially identical to each other, or may include insulating materials, different from each other, and in either case, an interlayer boundary may exist. The insulating layer 111 and the insulator 111P may include substantially the same insulating material, and may be integrated without a boundary. Among the plurality of build-up insulating layers 110-1, 110-2, and 110-3, remaining build-up insulating layers 110-2 and 110-3 may include substantially the same insulating material, but may include different insulating materials.

Each of the plurality of build-up wiring layers 120-1, 120-2, and 120-3 may include metal. The metal may include copper (Cu), aluminum (Al), silver (Ag), tin (Sn), gold (Au), nickel (Ni), lead (Pb), titanium (Ti), and/or alloys thereof, or the like. Preferably, copper (Cu) may be included, but is not limited thereto. Each of the plurality of build-up wiring layers 120-1, 120-2, and 120-3 may perform various functions according to a design. For example, a signal pattern, a power pattern, a ground pattern, or the like may be included. Each of these patterns may have various shapes such as a line, a plane, a pad, or the like.

The inner build-up wiring layer 120-1 among the plurality of build-up wiring layers 120-1, 120-2, and 120-3 may be disposed in the inner build-up insulating layer 110-1 among the plurality of build-up insulating layers 110-1, 110-2, and 110-3. Remaining build-up wiring layers 120-2 and 120-3 among the plurality of build-up wiring layers 120-1, 120-2, and 120-3 may be disposed on or in remaining build-up insulating layers 110-2 and 110-3 among the plurality of build-up insulating layers 110-1, 110-2, and 110-3, respectively. Among the plurality of build-up wiring layers 120-1, 120-2, and 120-3, the inner build-up wiring layer 120-1 may include an electrolytic plating layer (or electrolytic copper), and a sputtering layer and/or an electroless plating layer (or chemical copper) may be included in a portion of a side surface of only some microcircuits thereof as a seed metal layer. The remaining build-up wiring layers 120-2 and 120-3 may include an electroless plating layer (or chemical copper) and an electrolytic plating layer (or electrolytic copper), respectively. Alternatively, the remaining build-up wiring layers 120-2 and 120-3 may include a metal foil (or copper foil) and an electrolytic plating layer (or electrolytic copper). Alternatively, the remaining build-up wiring layers 120-2 and 120-3 may include the metal foil (or copper foil), an electroless plating layer (or chemical copper), and the electrolytic plating layer (or electrolytic copper). The remaining build-up wiring layers 120-2 and 120-3 may include a sputtering layer, instead of the electroless plating layer (or chemical copper), and both may be included, as necessary.

Each of the plurality of build-up via layers 130-1, 130-2, and 130-3 may include a metal. The metal may include copper (Cu), aluminum (Al), silver (Ag), tin (Sn), gold (Au), nickel (Ni), lead (Pb), titanium (Ti), and/or alloys thereof, or the like. Preferably, copper (Cu) may be included, but is not limited thereto. Each of the plurality of build-up via layers 130-1, 130-2, and 130-3 may include a filed via filling a via hole, but may also include a conformal via disposed along a wall surface of the via hole. The vias respectively included in the plurality of build-up via layers 130-1, 130-2, and 130-3 may perform various functions according to a design. For example, a ground via, a power via, a signal via, or the like may be included. Among the plurality of build-up via layers 130-1, 130-2, and 130-3, the inner build-up via layer 130-1 may have a tapered shape in the same direction as the build-up via layer 130-2 disposed therebelow in cross-sectional view, and may have a taper shape in a direction, opposite to that of the build-up via layer 130-3 disposed thereon in cross-sectional view.

An inner build-up via layer 130-1 among the plurality of build-up via layers 130-1, 130-2, and 130-3 may pass through the inner build-up insulating layer 110-1 among the plurality of build-up insulating layers 110-1, 110-2, and 110-3, and may be connected to the inner build-up wiring layer 120-1 among the plurality of build-up wiring layers 120-1, 120-2, and 120-3. Remaining build-up via layers 130-2 and 130-3 among the plurality of build-up via layers 130-1, 130-2, and 130-3 may pass through remaining build-up insulating layers 110-2 and 110-3 among the plurality of build-up insulating layers 110-1, 110-2, and 110-3, respectively, and may be connected to remaining build-up wiring layers 120-2 and 120-3 among the plurality of build-up wiring layers 120-1, 120-2, and 120-3, respectively. Each of the plurality of build-up via layers 130-1, 130-2, and 130-3 may include an electroless plating layer (or chemical copper) and an electrolytic plating layer (or electrolytic copper). A sputtering layer may be included, instead of the electroless plating layer (or chemical copper), and both may be included, as necessary.

The first and second resist layers 141 and 142 may include a liquid- or film-type solder resist, but is not limited thereto, and other types of insulating materials may be used. A surface treatment layer may be formed on a pattern exposed through the first opening 141h and/or the second opening 142h, as necessary. Alternatively, a metal bump may be formed on the pattern exposed through the first opening 141h and/or the second opening 142h.

Since others may be substantially the same as those described in the above-described printed circuit boards 100A, 100B, and 100C, overlapping description thereof will be omitted.

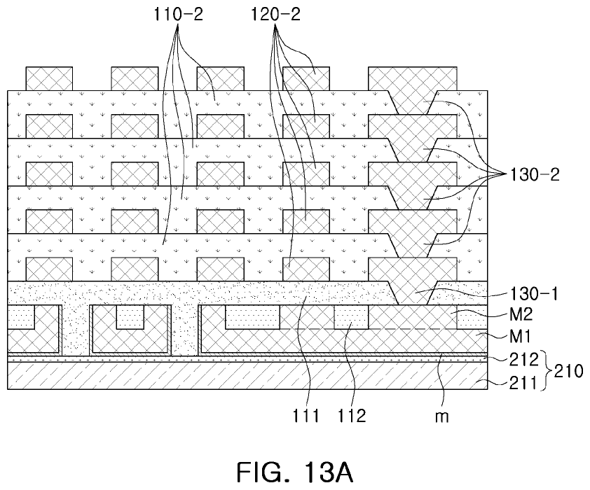

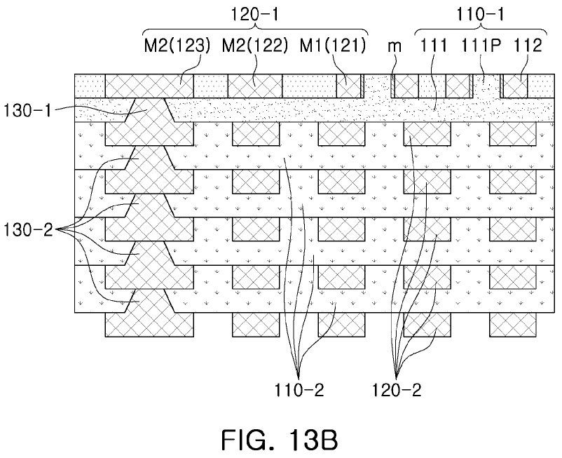

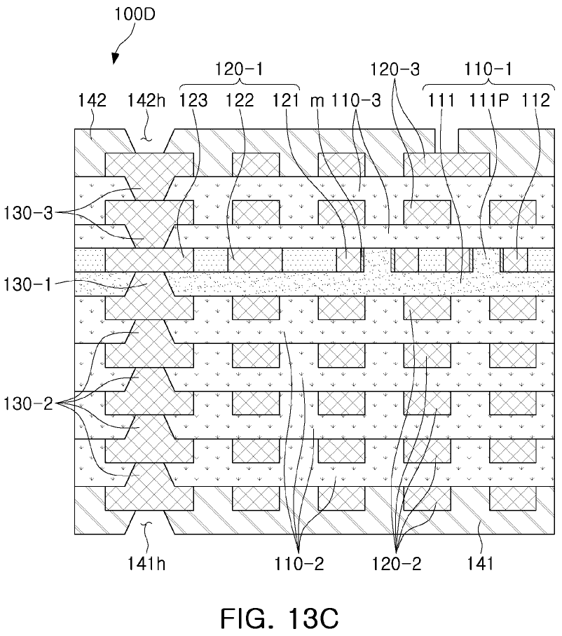

FIGS. 13A to 13C are process diagrams schematically illustrating an example of manufacturing the printed circuit board of FIG. 12.

Referring to the drawings, a method of manufacturing a printed circuit board 100D according to another example may further include, after forming a first insulating layer 111, forming a plurality of build-up insulating layers 110-2, a plurality of build-up wiring layers 120-2, and a plurality of build-up via layers 130-1 and 130-2, as compared to the manufacturing method of the printed circuit board 100B according to the above-described example. In addition, after polishing at least a portion of a seed metal layer m, at least a portion of a first plating layer M1, and at least a portion of a first insulating layer 111, formation of remaining plurality of build-up insulating layers 110-3, remaining plurality of build-up wiring layers 120-3, and remaining plurality of build-up via layers 130-3 may be further included. For example, in a method of manufacturing a printed circuit board 100D according to another example, a multilayer coreless substrate may be formed, before and after a detaching operation, in the manufacturing method of the printed circuit board 100B according to another example described above, Therefore, a structure of the printed circuit board 100B according to another example described above may be applied as an inner layer in a structure of a multilayer coreless substrate of a printed circuit board 100D according to another example.

A method of manufacturing a printed circuit board 100D according to another example may further include, after polishing at least a portion of a seed metal layer m, at least a portion of a first plating layer M1, and at least a portion of a first insulating layer 111, and after forming a plurality of build-up insulating layer 110-3, a plurality of build-up wiring layers 120-3, and a plurality of build-up via layers 130-3, forming first and second resist layers 141 and 142 on both sides of build-up insulating layers 110-1, 110-2, and 110-3, respectively. In addition, the method may further include forming first and second openings 141h and 142h at least partially exposing outermost build-up wiring layers 120-2 and 120-3 disposed on both sides of a plurality of build-up wiring layers 120-1, 120-2, and 120-3, to the first and second resist layers 141 and 142, respectively.

Hereinafter, a method of manufacturing a printed circuit board 100D according to another example will be described in more detail with reference to the drawings.

Referring to FIG. 13A, first and second insulating layers 111 and 112, first and second plating layers M1 and M2, and a seed metal layer m may be formed on a detachable substrate 210 by substantially the same process as FIGS. 9A to 9G described above. Next, a plurality of build-up insulating layers 110-2, a plurality of build-up wiring layers 120-2, and a plurality of build-up via layers 130-1 and 130-2 may be formed by a build-up process. The plurality of build-up insulating layers 110-2 may be formed by stacking uncured insulating materials and then curing them, and the plurality of build-up wiring layers 120-2 and the plurality of build-up via layers 130-1 and 130-2 may be formed by a plating process using SAP, MSAP, tenting, or the like, after processing via holes in the first insulating layer 111 and the plurality of build-up insulating layers 110-2.

Referring to FIG. 13B, a detachable substrate 210 may be removed. For example, the detachable substrate 210 may be removed by separating a detachable core 211 from a detachable layer 212. The remaining detachable layer 212 may be removed first, or may be removed in a second polishing operation to be described later. Next, on a side from which the detachable substrate 210 is removed, at least a portion of the seed metal layer m, at least a portion of the first plating layer M1, and at least a portion of the first insulating layer 111 may be polished. For example, the polishing may be performed until at least the second insulating layer 112 and the second plating layer M2 are exposed. As necessary, a portion of the second insulating layer 112 and a portion of the second plating layer M2 may also be polished. In addition, the remaining detachable layer 212 may also be polished. CMP may be used as the polishing process, but is not limited thereto, and other mechanical and/or chemical planarization processes may be used. After the polishing, a plurality of first circuit patterns 121 and a plurality of second circuit patterns 122, and a plurality of pad patterns 123, buried in the insulating materials (111, 111P, and 112), respectively, may be formed. An outermost build-up insulating layer 110-1 among the plurality of build-up insulating layers 110-1 and 110-2 may include the first and second insulating layers 111 and 112. An outermost build-up wiring layer 120-1 among the plurality of build-up wiring layers 120-1 and 120-2 may include the plurality of first circuit patterns 121, the plurality of second circuit patterns 122, and the plurality of pad patterns 123.

Referring to FIG. 13C, a plurality of build-up insulating layers 110-3, a plurality of build-up wiring layers 120-3, and a plurality of build-up via layers 130-3 may be formed on a side, opposite to a side on which the plurality of build-up insulating layers 110-2, the plurality of build-up wiring layers 120-2, and the plurality of build-up via layers 130-1 and 130-2 are formed by a build-up process. The plurality of build-up insulating layers 110-3 may be formed by stacking uncured insulating materials and then curing them, and the plurality of build-up wiring layers 120-3 and the plurality of build-up via layers 130-3 may be formed by a plating process using SAP, MSAP, tenting, or the like, after processing via holes in the plurality of build-up insulating layers 110-3. Next, first and second resist layers 141 and 142 may be formed on both sides of the plurality of build-up insulating layers 110-1, 110-2, and 110-3, respectively. In addition, first and second openings 141h and 142h at least partially exposing the outermost build-up wiring layer 120-2 and the outermost build-up wiring layer 120-3, among the plurality of build-up wiring layers 120-1, 120-2, and 120-3, may be formed in the first and second resist layers 141 and 142, respectively. A surface treatment layer may be formed on a pattern exposed through the first opening 141h and/or the second opening 142h, as necessary. Alternatively, a metal bump may be formed on the pattern exposed through the first opening 141h and/or the second opening 142h.

Since a printed circuit board 100D according to another example described above by a series of processes may be formed, and others may be substantially the same as those described in the above-described printed circuit boards 100A, 100B, 100C, and 100D, and the manufacturing method of the printed circuit boards 100A, 100B, and 100C described above, overlapping description thereof will be omitted.

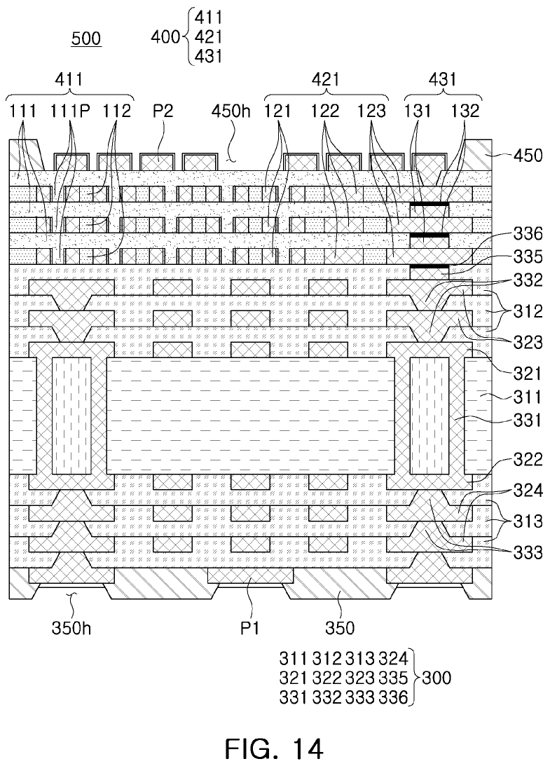

FIG. 14 is a schematic cross-sectional view of another example of a printed circuit board.

Referring to the drawings, a printed circuit board 500 according to another example may include a core-type first substrate unit 300, and a coreless-type second substrate unit 400 disposed on the first substrate unit 300. The core-type first substrate unit 300 may include a core insulating layer 311, a plurality of build-up insulating layers 312 and 313, a plurality of core wiring layers 321 and 322, a plurality of build-up wiring layers 323 and 324, a core via layer 331, and a plurality of build-up via layers 332 and 333. The coreless-type second substrate unit 400 may include a plurality of build-up insulating layers 411, a plurality of build-up wiring layers 421, and a plurality of build-up via layers 431. At least one of the plurality of build-up insulating layers 411 of the second substrate unit 400 may include first and second insulating layers 111 and 112, and an insulator 111P, as in the printed circuit board 100B according to another example described above. At least one of the plurality of build-up wiring layers 421 of the second substrate unit 400 may include a plurality of first circuit patterns 121, a plurality of second circuit patterns 122, and a plurality of pad patterns 123, as in the printed circuit board 100B according to another example described above. For example, in the second substrate unit 400, all of the plurality of build-up insulating layers 411 may include the first and second insulating layers 111 and 112 and the insulator 111P, and all of the plurality of build-up wiring layers 421 may include the plurality of first circuit patterns 121, the plurality of second circuit patterns 122, and the plurality of pad patterns 123. For example, the structure of the printed circuit board 100B according to another example described above may be applied to all layers of the second substrate unit 400 in a structure of a multilayer package substrate of the printed circuit board 100D according to another example. However, an example is not limited thereto, and may be applied to only some layers, as needed.

The printed circuit board 500 according to another example may further include first and second outer pads P1 and P2 and first and second resist layers 350 and 450, disposed in outermost portions of the first and second substrate units 300 and 400, respectively. The first resist layer 350 may have a plurality of first openings 350h exposing at least a portion of each of the plurality of first outer pads P1 disposed in an outermost portion of the first substrate unit 300. The second resist layer 450 may have one second opening 450h exposing at least a portion of each of the plurality of second outer pads P2 disposed in an outermost portion of the second substrate unit 400.

Hereinafter, components of a printed circuit board 500 according to another example will be described in more detail with reference to the drawings.

A first substrate unit 300 may be a multilayer core-type substrate. For example, the first substrate unit 300 may include a core insulating layer 311, a plurality of core wiring layers 321 and 322 disposed on both surfaces of the core insulating layer 311, a core via layer 331 passing through the core insulating layer 311 and connecting the plurality of core wiring layers 321 and 322, a plurality of build-up insulating layers 312 and 313 respectively disposed on both surfaces of the core insulating layer 311, a plurality of build-up wiring layers 323 and 324 respectively disposed on or in plurality of build-up insulating layers 312 and 313, and a plurality of build-up via layers 332 and 333 passing through at least one of the plurality of build-up insulating layers 312 and 313 and respectively connected to at least one of the plurality of build-up wiring layers 323 and 324. However, the first substrate unit 300 may be replaced with a multilayer coreless-type substrate, as necessary.

The core insulating layer 311 may include an insulating material. The insulating material may include a thermosetting resin such as an epoxy resin, a thermoplastic resin such as polyimide, a material in which these insulating resins are mixed with an inorganic filler such as silica or the like, or a resin impregnated into a core material of glass fiber (glass cloth, glass fabric) together with an inorganic filler, for example, an insulating material of a copper clad laminate (CCL), or the like, but is not limited thereto. The core insulating layer 311 may be thicker than each of the plurality of build-up insulating layers 312 and 313, but is not limited thereto.

Each of the plurality of build-up insulating layers 312 and 313 may include an insulating material. The insulating material may include a thermosetting resin such as an epoxy resin, a thermoplastic resin such as polyimide, a material in which these insulating resins are mixed with an inorganic filler such as silica or the like, or a resin impregnated into a core material of glass fiber (glass cloth, glass fabric) together with an inorganic filler, for example, an insulating material of Ajinomoto Build-up Film (ABF), a prepreg, a resin coated copper (RCC), or the like, but is not limited thereto. The numbers of layers of the plurality of build-up insulating layers 312 and 313 are not particularly limited, and may be the same as each other, but are not limited thereto.

Each of the plurality of core wiring layers 321 and 322 may include a metal. The metal may include copper (Cu), aluminum (Al), silver (Ag), tin (Sn), gold (Au), nickel (Ni), lead (Pb), titanium (Ti), or alloys thereof, or the like. Preferably, copper (Cu) may be included, but is not limited thereto. Each of the plurality of core wiring layers 321 and 322 may include an electroless plating layer (or chemical copper) and an electrolytic plating layer (or electrolytic copper), but is not limited thereto. A sputtering layer may be formed, instead of the electroless plating layer, or both may be included. In addition, a copper foil may be further included. Each of the plurality of core wiring layers 321 and 322 may perform various functions according to a design of a layer corresponding thereto. For example, a ground pattern, a power pattern, a signal pattern, or the like may be included. Each of these patterns may include a line pattern, a plane pattern, and/or a pad pattern.

Each of the plurality of build-up wiring layers 323 and 324 may include a metal. The metal may include copper (Cu), aluminum (Al), silver (Ag), tin (Sn), gold (Au), nickel (Ni), lead (Pb), titanium (Ti), or alloys thereof, or the like. Preferably, copper (Cu) may be included, but is not limited thereto. Each of the plurality of build-up wiring layers 323 and 324 may include an electroless plating layer (or chemical copper) and an electrolytic plating layer (or electrolytic copper), but is not limited thereto. A sputtering layer may be formed, instead of the electroless plating layer, or both may be included. In addition, a copper foil may be further included. Each of the plurality of build-up wiring layers 323 and 324 may perform various functions according to a design of a layer corresponding thereto. For example, a ground pattern, a power pattern, a signal pattern, or the like may be included. Each of these patterns may include a line pattern, a plane pattern, and/or a pad pattern.

The core via layer 331 may include a through-via. The through-via may include a metal layer formed on a wall surface of a through-hole, and a plug filling the metal layer. The metal layer may include copper (Cu), aluminum (Al), silver (Ag), tin (Sn), gold (Au), nickel (Ni), lead (Pb), titanium (Ti), or an alloy thereof, and preferably may include copper (Cu), but is not limited thereto. The plug may contain ink made of an insulating material. The metal layer may include, but is not limited to, an electroless plating layer (or chemical copper) and an electrolytic plating layer (or electrolytic copper). A sputtering layer may be formed, instead of the electroless plating layer, or both may be included. The core via layer 331 may perform various functions according to a design. For example, the core via layer 331 may include a ground via, a power via, a signal via, or the like.

The plurality of build-up via layers 332 and 333 may include a micro via. The micro via may be a filed via filling a via hole, but may also be a conformal via disposed along a wall surface of the via hole. Micro vias may be arranged in a stacked type and/or a staggered type. Each of the plurality of build-up via layers 332 and 333 may include metal, such as copper (Cu), aluminum (Al), silver (Ag), tin (Sn), gold (Au), nickel (Ni), lead (Pb), titanium (Ti), and/or alloys thereof, or the like, and preferably copper (Cu), but is not limited thereto. Each of the plurality of build-up via layers 332 and 333 may include an electroless plating layer (or chemical copper) and an electrolytic plating layer (or electrolytic copper), but is not limited thereto. A sputtering layer may be formed, instead of the electroless plating layer, or both may be included. The plurality of build-up via layers 332 and 333 may perform various functions according to a design of a layer corresponding thereto. For example, a ground via, a power via, a signal via, or the like may be included.

The second substrate unit 400 may be a coreless-type multilayer build-up substrate including a microcircuit. For example, the second substrate unit 400 may include a plurality of build-up insulating layers 411, a plurality of build-up wiring layers 421 respectively disposed in the plurality of build-up insulating layers 411, and a plurality of build-up via layers 431 respectively passing through at least one of the plurality of build-up insulating layers 411 and connected to at least one of the plurality of build-up wiring layers 421.

The plurality of build-up insulating layers 411 may include an insulating material, respectively. The insulating material may include a thermosetting resin such as an epoxy resin, a thermoplastic resin such as polyimide, or a material including an inorganic filler, an organic filler, and/or glass fiber (glass cloth, glass fabric) together with a resin. For example, the insulating material may be a non-photosensitive insulating material such as Ajinomoto Build-up Film (ABF), a prepreg (PPG), or the like, but is not limited thereto, and other polymer materials may be used. In addition, the insulating material may be a photosensitive insulating material such as a photoimageable dielectric (PID) or the like.

At least one build-up insulating layer 411 among the plurality of build-up insulating layers 411 may include a plurality of insulating layers 111 and 112 and an insulator 111P. For example, all of the build-up insulating layers 411 may include the plurality of insulating layers 111 and 112 and the insulator 111P, respectively. The plurality of insulating layers 111 and 112 may include insulating materials, substantially identical to each other, or may include insulating materials, different from each other, and in either case, an interlayer boundary may exist. The insulating layer 111 and the insulator 111P may include substantially the same insulating material, and may be integrated without a boundary.

Each of the plurality of build-up wiring layers 421 may include a metal. The metal may include copper (Cu), aluminum (Al), silver (Ag), tin (Sn), gold (Au), nickel (Ni), lead (Pb), titanium (Ti), and/or alloys thereof, or the like. Preferably, copper (Cu) may be included, but is not limited thereto. Each of the plurality of build-up wiring layers 421 may perform various functions according to a design. For example, a signal pattern, a power pattern, a ground pattern, or the like may be included. Each of these patterns may have various shapes such as a line, a plane, a pad, or the like.

At least one build-up wiring layer 421 of the plurality of build-up wiring layers 421 may include a plurality of first circuit patterns 121, a plurality of second circuit patterns 122, and a plurality of pad patterns 123. For example, all of the build-up wiring layers 421 may include a plurality of first circuit patterns 121, second circuit patterns 122, and pad patterns 123, respectively. Each of the plurality of build-up wiring layers 421 may include an electrolytic plating layer (or electrolytic copper), and a sputtering layer and/or an electroless plating layer (or chemical copper) may be included in a portion of a side surface of only some microcircuits thereof as a seed metal layer.

Each of the plurality of build-up via layers 431 may include a metal bump 131 filling a via hole. Each of the metal bumps 131 may include metal. The metal may include copper (Cu), aluminum (Al), silver (Ag), tin (Sn), gold (Au), nickel (Ni), lead (Pb), titanium (Ti), and/or alloys thereof, or the like. Preferably, copper (Cu) may be included, but is not limited thereto. A low melting point metal 132, for example, solder, may be disposed on each of the metal bumps 131, and may have a melting point lower than a melting point of the metal bump 131 or a melting point of the pad pattern 123. Each of the metal bumps 131 may perform various functions according to a design. For example, a metal bump for ground, a metal bump for power, a metal bump for signal, or the like may be included.

The plurality of build-up via layers 431 may pass through the first insulating layer 111 among the plurality of build-up insulating layers 411, and may be connected to the pad pattern 123 among the plurality of build-up wiring layers 421. For example, each of the metal bumps 131 may be directly connected to a pad pattern 123 therebelow. In addition, each of the metal bumps 131 may be connected to a pad pattern 123 thereon through the low melting point metal 132.

A metal bump 335 and a low melting point metal 336 may also be formed on an outermost portion of the first substrate unit 300 connected to the second substrate unit 400. The metal bump 335 and the low melting point metal 336 may be substantially the same as those described for the metal bump 131 and the low melting point metal 132.

The first and second resist layers 350 and 450 may include a liquid- or film-type solder resist, but is not limited thereto, and other types of insulating materials may be used. A first surface treatment layer may be disposed on each of the plurality of first outer pads P1 exposed through the plurality of first openings 350h. A second surface treatment layer may be disposed on each of the plurality of second outer pads P2 exposed through the one second opening 450h.

Each of the first and second outer pads P1 and P2 may include a metal. The metal may include copper (Cu), aluminum (Al), silver (Ag), tin (Sn), gold (Au), nickel (Ni), lead (Pb), titanium (Ti), and/or alloys thereof, or the like. Preferably, copper (Cu) may be included, but is not limited thereto. Each of the first and second outer pads P1 and P2 may perform various functions according to a design. For example, an outer pad for ground, an outer pad for power, and an outer pad for signals may be included. Each of the first and second outer pads P1 and P2 may include an electroless plating layer (or chemical copper) and an electrolytic plating layer (or electrolytic copper), but is not limited thereto. A sputtering layer may be formed, instead of the electroless plating layer, or both may be included. In addition, copper foil may be further included. Each of the first and second outer pads P1 and P2 may include a pattern portion, and at least some of them may further include a via portion.

The first and second surface treatment layers are not particularly limited as long as they may be known in the art, and, for example, may be formed by electrolytic gold plating, electroless gold plating, organic solderability preservative (OSP) or electroless tin plating, electroless silver plating, electroless nickel plating/substitution gold plating, direct immersion gold (DIG) plating, hot air solder leveling (HASL), or the like, but are not limited thereto.

Since others may be substantially the same as those described in the above-described printed circuit boards 100A, 100B, 100C, and 100D, overlapping description thereof will be omitted.

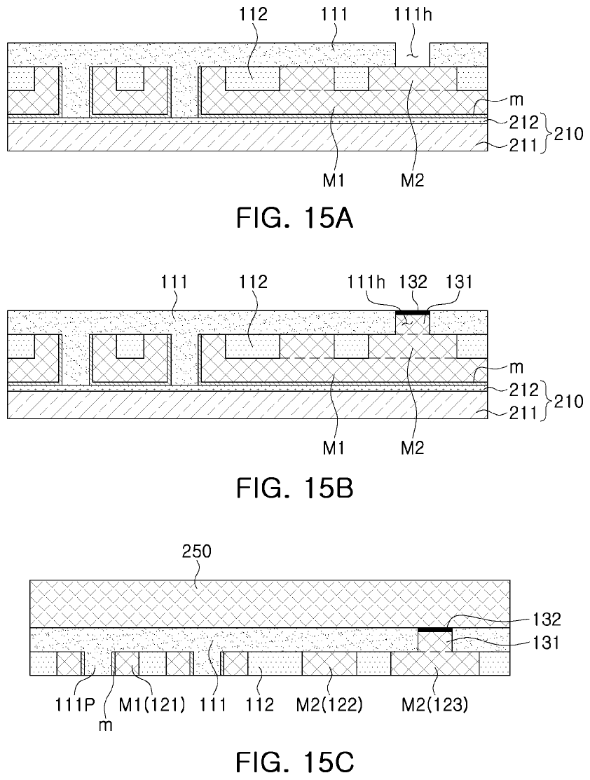

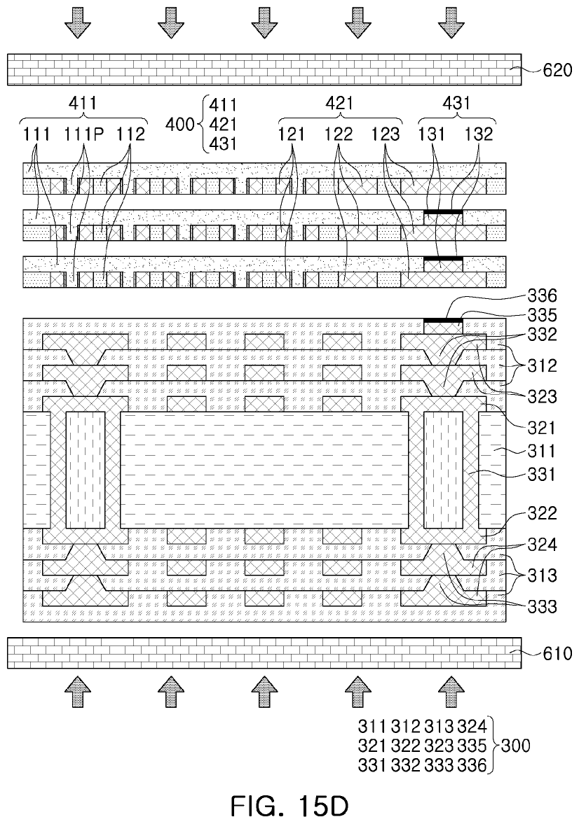

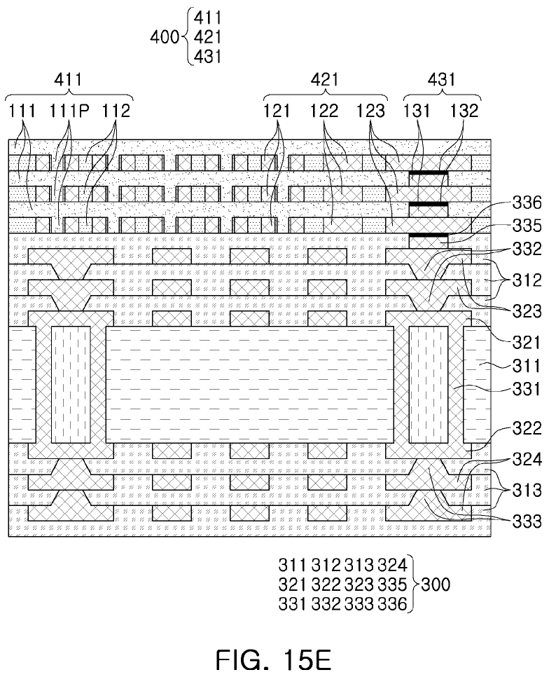

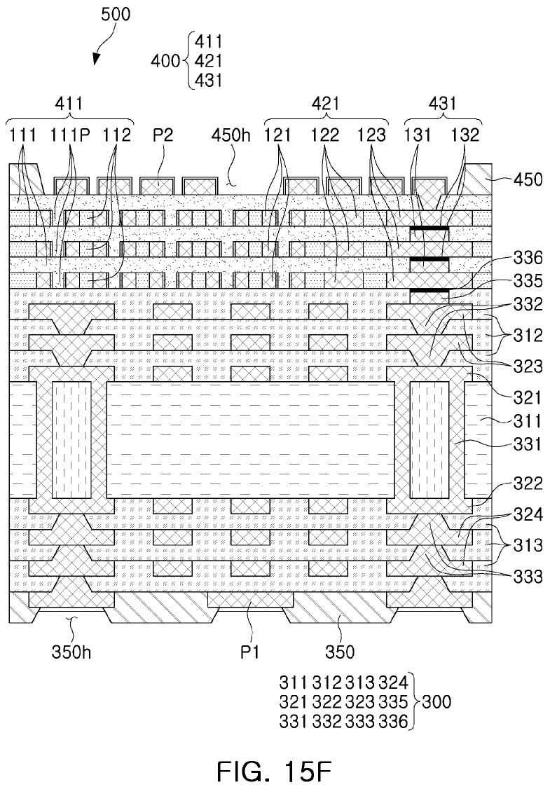

FIGS. 15A to 15F are process diagrams schematically illustrating an example of manufacturing the printed circuit board of FIG. 14.

Referring to the drawings, a method of manufacturing a printed circuit board 500 according to another example may include preparing a first substrate unit 300 having a core-type, preparing a second substrate unit 400 having a coreless-type, and stacking the first and second substrate units 300 and 400 in a batch-wise manner. In the preparing a second substrate unit 400, a substrate in which a metal bump 131 passing through a first insulating layer 111 and connected to a pad pattern 123, and a low melting point metal 132 disposed on the metal bump 131 are further formed is provided as a plurality of substrates in a structure of a printed circuit board 100B according to another example described above. For example, a method of manufacturing these substrates may further include, after forming a first insulating layer 111, forming an opening 111h exposing a plating layer M2 in the first insulating layer 111, forming a metal bump 131 in the opening 111h, and forming a low melting point metal 132 on the metal bump 131, as compared to the manufacturing method of the printed circuit board 100B according to the above-described example. Therefore, a structure of the printed circuit board 100B according to another example described above may be applied to all layers of a second substrate unit 400 in a structure of a multilayer package substrate of a printed circuit board 100D according to another example.

A method of manufacturing a printed circuit board 500 according to another example may further include, after the stacking the first and second substrate units 300 and 400 in a batch-wise manner, forming first and second outer pads P1 and P2 and first and second resist layers 350 and 450 on first and second substrate units 300 and 400, respectively. In addition, formation of first and second openings 350h and 450h in the first and second resist layers 350 and 450 may be further included.

Hereinafter, a method of manufacturing the printed circuit board 500 according to another example will be described in more detail with reference to the drawings.

Referring to FIG. 15A, first and second insulating layers 111 and 112, first and second plating layers M1 and M2, and a seed metal layer m may be formed on a detachable substrate 210 by substantially the same process as FIGS. 9A to 9G described above. Next, an opening 111h exposing the second plating layer M2 may be formed in the first insulating layer 111. The opening 111h may be formed by a photolithography process, when the first insulating layer 111 includes a photosensitive insulating material, and may be formed by a laser process, when the first insulating layer 111 includes a non-photosensitive insulating material.

Referring to FIG. 15B, a metal bump 131 may be formed in the opening 111h, and a low melting point metal 132 may be formed on the metal bump 131. The metal bump 131 may be formed by electrolytic plating, for example, as electrolytic copper, but is not limited thereto. The low melting point metal 132 may be formed by various known methods such as coating, plating, or the like.

Referring to FIG. 15C, the detachable substrate 210 may be removed. For example, the detachable substrate 210 may be removed by separating a detachable core 211 from a detachable layer 212. The remaining detachable layer 212 may be removed first, or may be removed in a second polishing operation to be described later. Next, on a side from which the detachable substrate 210 is removed, at least a portion of the seed metal layer m, at least a portion of the first plating layer M1, and at least a portion of the first insulating layer 111 may be polished. For example, the second insulating layer 112 and the second plating layer M2 may be polished until they are exposed. As necessary, a portion of the second insulating layer 112 and a portion of the second plating layer M2 may also be polished. In addition, the remaining detachable layer 212 may also be polished. CMP may be used as the polishing process, but is not limited thereto, and other mechanical and/or chemical planarization processes may be used. In the polishing process, an opposite side may be protected with a mask film 250. After polishing, a plurality of first circuit patterns 121, a plurality of second circuit patterns 122, and a plurality of pad patterns 123, buried in the insulating materials (111, 111P, and 112), respectively, may be formed. In addition, the metal bump 131 and the low melting point metal 132 may be formed on the pad pattern 123.

Referring to FIGS. 15D and 15E, a double-sided build-up process may be performed with centering on a core material such as CCL or the like, to prepare a first substrate unit 300 having a core-type and the above-described structure, a second substrate unit 400 including a plurality of substrates, manufactured in FIGS. 15A to 15C described above, may be disposed on the first substrate unit 300, and, then, cover films 610 and 620 may be used to collectively stack them. A metal bump 335 and a low melting point metal 336 may be formed in an outermost portion of the first substrate unit 300 connected to the second substrate unit 400. A multi-layered package substrate structure in which the second substrate unit 400 having a coreless-type is disposed on the first substrate unit 300 having a core-type may be formed by such stacking in a batch-wise manner.

Referring to FIG. 15F, first and second outer pads P1 and P2 and first and second resist layers 350 and 450 may be formed in outermost portions of the first and second substrate units 300 and 400, respectively. Also, first and second openings 350h and 450h exposing at least a portion of each of the first and second outer pads P1 and P2 may be formed in the first and second resist layers 350 and 450, respectively. The first and second outer pads P1 and P2 may be formed by a plating process using SAP, MSAP, tenting, or the like. The first and second resist layers 350 and 450 may be formed by coating and then curing a solder resist, or by stacking and then curing a film-type solder resist. The first and second openings 350h and 450h may be formed by a photolithography process. As necessary, a first surface treatment layer may be formed on each of the plurality of first outer pads P1 exposed through the plurality of first openings 350h, and exposed through one second opening 450h, and a second surface treatment layer may be formed on each of the plurality of second outer pads P2.

A printed circuit board 500 according to another example described above may be formed by a series of processes, and others may be substantially the same as those described in above-described printed circuit boards 100A, 100B, 100C, 100D, and 500, and manufacturing methods of the printed circuit boards 100A, 100B, 100C, and 100D, overlapping description thereof will be omitted.

In the present disclosure, the expression of covering may include a case of covering at least a portion as well as a case of covering an entire portion, and may also include a case of directly covering as well as a case of indirectly covering.

In the present disclosure, the expression of filling may include not only a case of completely filling but also a case of approximately filling, and may include, for example, a case in which some intervals, voids, or the like exists.

In the present disclosure, a thickness, a width, a line width, or the like may be measured using a scanning microscope or an optical microscope based on a polished or cut cross-section of a printed circuit board. When the thickness, the width, the line width, or the like are not constant, the thickness, the width, the line width, or the like may be compared with an average value of values measured at five (5) random points.

In the present disclosure, determination may be performed by including errors in process, positional deviations, errors in measurement, and the like, substantially occurring in a manufacturing process.

For example, having substantially the same line width may include not only a case of being completely numerically identical, but also a case of having substantially similar numerical values within an error range. In addition, being substantially coplanar may include not only a case of being completely in the same plane, but also a case of being in approximately the same plane within an error range.

In the present disclosure, the same insulating material may mean not only the completely same insulating material, but also include the same type of insulating material. Therefore, a composition of the insulating material may be substantially the same, but a specific composition ratio thereof may be slightly different.

In the present disclosure, the meaning of (in) cross-sectional view may mean a cross-sectional shape when an object is vertically cut, a cross-sectional shape when the object vertically cut, or a cross-sectional shape when the object is viewed from a side-view. In addition, the meaning of (in) plan view may mean a plane shape when an object is horizontally cut, or a plane shape when the object is viewed from a plan-view or bottom-view.

In the present disclosure, a lower side, a lower portion, a lower surface, or the like may be used to mean a downward direction, based on the cross-section of the drawing for convenience, and an upper side, an upper portion, an upper surface, or the like may be used to mean the opposite direction. However, the above descriptions are to define a direction for convenience of description, and the scope of the claims are not particularly limited by the description of this direction, of course, and concepts of upper and lower directions may be changed at any time.

In the present disclosure, the meaning of being connected is a concept including not only being directly connected but also being indirectly connected by an adhesive layer or the like. In addition, the meaning of being electrically connected is a concept including both a physical connection and a physical non-connection. In addition, expressions such as first, second, and the like are used to distinguish one component from another, and do not limit the order and/or importance of components. In some cases, without departing from the scope of rights, a first component may be referred to as a second component, and similarly, a second component may be referred to as a first component.

The expression “one example” used in the present disclosure does not mean the same embodiment to each other, but may be provided for emphasizing and explaining different unique features. However, the above-mentioned examples do not exclude that the above-mentioned examples are implemented in combination with the features of other examples. For example, although the description in a specific example is not described in another example, it can be understood as an explanation related to another example, unless otherwise described or contradicted by the other example.

The terms used in the present disclosure are used only to illustrate various examples and are not intended to limit the present inventive concept. Singular expressions include plural expressions unless the context clearly dictates otherwise.

As one of various effects of the present disclosure, a printed circuit board capable of forming a microcircuit and a manufacturing method thereof may be provided.

As another effect of various effects of the present disclosure, a printed circuit board having high reliability and a manufacturing method thereof may be provided.

While example embodiments have been illustrated and described above, it will be apparent to those skilled in the art that modifications and variations could be made without departing from the scope of the present disclosure as defined by the appended claims.

What is claimed is:

1. A printed circuit board comprising:
a first insulating layer;
a plurality of first circuit patterns respectively disposed on the first insulating layer;
a second insulating layer disposed on the first insulating layer and covering a portion of a side surface of each of the plurality of first circuit patterns; and
an insulator disposed between at least one pair of adjacent first circuit patterns, among the plurality of first circuit patterns, and integrated with the first insulating layer.

2. The printed circuit board of claim 1, wherein the insulator extends from a portion of the first insulating layer between the at least one pair of adjacent first circuit patterns.

3. The printed circuit board of claim 1, wherein a boundary exists between the first insulating layer and the second insulating layer, and
a boundary does not exist between the first insulating layer and the insulator.

4. The printed circuit board of claim 1, wherein the insulator is disposed between one side surfaces of the at least one pair of adjacent first circuit patterns, facing each other, and the second insulating layer covers the other side surface of each of the at least one pair of adjacent first circuit patterns, opposite to each of the one side surfaces.

5. The printed circuit board of claim 4, wherein a seed metal layer is disposed between the insulator and the one side surface of each of the at least one pair of adjacent first circuit patterns.

6. The printed circuit board of claim 5, wherein the seed metal layer is not disposed on the other side surface, an upper surface, and a lower surface of each of the at least one pair of adjacent first circuit patterns.

7. The printed circuit board of claim 1, wherein an upper surface of each of the plurality of first circuit patterns, an upper surface of the second insulating layer, and an upper surface of the insulator are substantially coplanar with each other, and
a lower surface of each of the plurality of first circuit patterns and a lower surface of the second insulating layer are substantially coplanar with each other.

8. The printed circuit board of claim 1, wherein, in a cross-section, one first circuit pattern among the at least one pair of adjacent first circuit patterns, the insulator, the other first circuit pattern among the at least one pair of adjacent first circuit patterns, and the second insulating layer are repeatedly arranged in order.

9. The printed circuit board of claim 8, wherein, in the repetitive arrangement in the cross-sectional view, a line width or width is repeated in order of W1, W2, W1, and W3, in which W1 is a line width of the one first circuit pattern and is a line width of the other first circuit pattern, among the at least one pair of adjacent first circuit patterns, W2 is a width of the insulator, and W3 is a width of the second insulating layer.

10. The printed circuit board of claim 1, wherein the first and second insulating layers comprise insulating materials, different from each other.

11. The printed circuit board of claim 1, wherein the first and second insulating layers comprise insulating materials, substantially identical to each other.

12. The printed circuit board of claim 4, further comprising a second circuit pattern disposed on the first insulating layer and having a line width, wider than a line width of each of the plurality of first circuit patterns in a cross-sectional view,
wherein the insulator is disposed to be spaced apart from both side surfaces of the second circuit pattern, and the second insulating layer covers the both side surfaces of the second circuit pattern.

13. The printed circuit board of claim 12, further comprising a pad pattern disposed on the first insulating layer,
wherein the insulator is disposed to be spaced apart from both side surfaces of the pad pattern, and the second insulating layer covers the both side surfaces of the pad pattern.

14. The printed circuit board of claim 13, wherein the printed circuit board comprises a plurality of build-up insulating layers, a plurality of build-up wiring layers, and a plurality of build-up via layers,
wherein at least one build-up insulating layer, among the plurality of build-up insulating layers, includes the first insulating layer, the second insulating layer, and the insulator, and
at least one build-up wiring layer, among the plurality of build-up wiring layers, includes the plurality of first circuit patterns, the second circuit pattern, and the pad pattern.

15. The printed circuit board of claim 14, wherein, in the at least one build-up wiring layer including the plurality of first circuit patterns, the second circuit pattern, and the pad pattern, a seed metal layer is disposed on one side surface of each of the plurality of first circuit patterns, and the seed metal layer is not disposed on upper and lower surfaces of each of the plurality of first circuit patterns, upper and lower surfaces of the second circuit pattern, and upper and lower surfaces of the pad pattern, and
in another build-up wiring layer, among the plurality of build-up wiring layers, except for the at least one build-up wiring layer including the plurality of first circuit patterns, the second circuit pattern, and the pad pattern, another seed metal layer is disposed on an upper surface or a lower surface of a circuit pattern.

16. The printed circuit board of claim 14, wherein an outermost build-up insulating layer among the plurality of build-up insulating layers includes the first and second insulating layers and the insulator, and
an outermost build-up wiring layer among the plurality of build-up wiring layers includes the plurality of first circuit patterns, the second circuit pattern and the pad pattern.

17. The printed circuit board of claim 16, further comprising a resist layer disposed on the outermost build-up insulating layer among the plurality of build-up insulating layers,
wherein the resist layer is in contact with the second insulating layer and the insulator, respectively.

18. The printed circuit board of claim 14, wherein an inner build-up insulating layer among the plurality of build-up insulating layers includes a build-up insulating layer including the first and second insulating layers and the insulator, and
an inner build-up wiring layer among the plurality of build-up wiring layers includes the plurality of first circuit patterns, the second circuit pattern and the pad pattern.

19. The printed circuit board of claim 13, further comprising a core-type first substrate unit, and a coreless-type second substrate unit disposed on the first substrate unit and including a plurality of build-up insulating layers, a plurality of build-up wiring layers, and a plurality of build-up via layers,
wherein at least one build-up insulating layer among the plurality of build-up insulating layers includes the first insulating layer, the second insulating layer, and the insulator, and
at least one build-up wiring layer among the plurality of build-up wiring layers comprises the plurality of first circuit patterns, the second circuit pattern, and the pad pattern.

20. The printed circuit board of claim 19, wherein the plurality of build-up insulating layers comprise the first insulating layer, the second insulating layer, and the insulator, and
the plurality of build-up wiring layers comprise the plurality of first circuit patterns, the second circuit pattern, and the pad pattern.

21. The printed circuit board of claim 20, further comprising:
in the first insulating layer to connect to the pad pattern and a low melting point metal disposed on the metal bump.

22. A printed circuit board comprising:
an insulating material; and
a plurality of first circuit patterns respectively embedded in the insulating material,
wherein a seed metal layer is disposed on one side surface, of at least one pair of adjacent first circuit patterns, among the plurality of first circuit patterns, respectively facing each other, and the seed metal layer is not disposed on the other side surface, opposite to the one side surface.

23. The printed circuit board of claim 22, wherein the seed metal layer is not disposed on upper and lower surfaces of each of the at least one pair of adjacent first circuit patterns.

24. The printed circuit board of claim 23, further comprising:
a second circuit pattern embedded in the insulating material; and
a pad pattern embedded in the insulating material,
wherein the seed metal layer is not disposed on both side surfaces and a lower surface of the second circuit pattern, and on both side surfaces and a lower surface of the pad pattern.

25. A method for manufacturing a printed circuit board, comprising:
forming a first dry film on a detachable substrate;
forming a plurality of dry film patterns spaced apart from each other on the detachable substrate by patterning the first dry film;
forming a seed metal layer covering each of the plurality of dry film patterns on the detachable substrate;
forming a first plating layer on the seed metal layer along the detachable substrate and the plurality of dry film patterns;
forming a second insulating layer on the first plating layer to cover the first plating layer and to fill a space between side surfaces of the first plating layer;
polishing at least a portion of the second insulating layer, at least a portion of the first plating layer, and at least a portion of the seed metal layer;
removing the plurality of dry film patterns remaining between side surfaces of the seed metal layer;
forming a first insulating layer on the detachable substrate to cover the second insulating layer and the first plating layer and to fill a space between the side surfaces of the seed metal layer;
removing the detachable substrate; and
polishing at least a portion of the seed metal layer, at least a portion of the first plating layer, and at least a portion of the first insulating layer.

26. The method of claim 25, wherein, in the forming a plurality of dry film patterns, if a width of each of the plurality of dry film patterns in a cross-sectional view is n, a separation distance between the plurality of dry film patterns in the cross-sectional view substantially satisfies 3n.

27. The method of claim 26, wherein, in the forming a first plating layer, a thickness or a width of the first plating layer in the cross-sectional view substantially satisfies n.

28. The method of claim 25, wherein the polishing at least a portion of the second insulating layer, at least a portion of the first plating layer, and at least a portion of the seed metal layer is performed until at least the plurality of dry film patterns are exposed from a side, opposite to a side on which the detachable substrate is disposed, and
the polishing at least a portion of the seed metal layer, at least a portion of the first plating layer, and at least a portion of the first insulating layer is performed until at least the second insulating layer is exposed from the side from which the detachable substrate is removed.

29. The method of claim 25, further comprising, after the forming a first plating layer:
removing a portion of the first plating layer and a portion of the seed metal layer, disposed on both end portions of each of the plurality of dry film patterns in a plan view.

30. The method of claim 25, further comprising, after the forming a first plating layer:
forming a second dry film on the first plating layer;
forming a plurality of opening patterns exposing the first plating layer by patterning the second dry film;
forming second plating layers in the plurality of opening patterns; and
removing the second dry film.

31. The method of claim 30, wherein, in the forming a second insulating layer, the second insulating layer further covers the second plating layers, and further fills a space between the second plating layers, and a space between the first plating layer and each of the second plating layers,
in the polishing at least a portion of the second insulating layer, at least a portion of the first plating layer, and at least a portion of the seed metal layer, at least a portion of each of the second plating layers is further polished, and
in the forming a first plating layer, the first insulating layer further covers the second plating layers.

32. The method of claim 31, further comprising, after the forming the first insulating layer:
forming a plurality of first build-up insulating layers, a plurality of first build-up wiring layers, and a plurality of first build-up via layers.

33. The method of claim 32, further comprising, after the polishing at least a portion of the seed metal layer, at least a portion of the first plating layer, and at least a portion of the first insulating layer:
forming a plurality of second build-up insulating layers, a plurality of second build-up wiring layers, and a plurality of second build-up via layers on a side, opposite to a side on which the plurality of first build-up insulating layers, the plurality of first build-up wiring layers, and the plurality of first build-up via layers are formed.

34. The method of claim 31, further comprising, after the forming the first insulating layer:
forming an opening exposing the second plating layer, in the first insulating layer;
forming a metal bump in the opening; and
forming a low melting point metal on the metal bump.

35. The method of claim 34, comprising:
preparing a core-type first substrate unit and a coreless-type second substrate unit, and
stacking the first and second substrate units in a batch-wise manner,
wherein the second substrate unit includes a plurality of substrates formed through the operations recited in claim 34.

36. A printed circuit board comprising:
a first insulating layer including a base portion and a protruding portion protruding from the base portion;
a second insulating layer disposed on the base portion of the first insulating layer and including an opening in which the protruding portion of the first insulating layer is disposed; and
first circuit patterns spaced apart from each other, and disposed in the opening and on opposing side surfaces of the protruding portion of the first insulating layer, respectively.

37. The printed circuit board of claim 36, wherein one of the first circuit patterns includes a first side surface facing the protruding portion and a second side surface opposing the first side surface of the one of the first circuit patterns,
another of the first circuit patterns includes a first side surface facing the protruding portion and a second side surface opposing the first side surface of the another of the first circuit patterns, and
the second side surface of the one of the first circuit patterns and the second side surface of the another of the first circuit patterns are in contact with the second insulating layer.

38. The printed circuit board of claim 37, wherein third and fourth side surfaces of the one of the first circuit patterns opposing each other and connected to the first and second side surfaces of the one of the first circuit patterns are in contact with the second insulating layer, and
third and fourth side surfaces of the another of the first circuit patterns opposing each other and connected to the first and second side surfaces of the another of the first circuit patterns are in contact with the second insulating layer.

39. The printed circuit board of claim 36, further comprising a seed metal layer disposed between the protruding portion of the first insulating layer and each of the first circuit patterns.

40. The printed circuit board of claim 39, wherein the seed metal layer includes one portion between the protruding portion and one of the first circuit patterns and another portion between the protruding portion and another of the first circuit patterns, and
the one portion and the another portion of the seed metal layer are spaced apart from each other.

41. The printed circuit board of claim 36, wherein an upper surface of each of the first circuit patterns, an upper surface of the second insulating layer, and an upper surface of the protruding portion of the first insulating layer are substantially coplanar with each other.

42. The printed circuit board of claim 36, wherein a lower surface of each of the first circuit patterns and a lower surface of the second insulating layer are in contact with the base portion of the first insulating layer and are substantially coplanar with each other.

43. The printed circuit board of claim 36, further comprising a second circuit pattern or a pad pattern disposed on the base portion of the first insulating layer and in another opening of the second insulating layer.

44. The printed circuit board of claim 43, wherein the second circuit pattern or the pad pattern includes first and second side surfaces opposing each other and third and fourth side surface opposing each other and connected to the first and second side surfaces, and
the first through fourth side surfaces of the second circuit pattern or the pad pattern are in contact with the second insulating layer.

45. The printed circuit board of claim 43, further comprising:
in the first insulating layer to connect to the pad pattern and a low melting point metal disposed on the metal bump.

46. A printed circuit board comprising:
a first insulating layer including a base portion and protruding portions protruding from the base portion;
first circuit patterns disposed on the base portion of the first insulating layer and spaced apart from each other in one direction; and
a second insulating layer disposed on the first insulating layer,
wherein the second insulating layer includes portions alternately disposed with the protruding portions of the first insulating layer in the one direction to separate adjacent two of the first circuit patterns from each other in the one direction.

47. The printed circuit board of claim 46, wherein each of the first circuit patterns includes side surfaces opposing each other in the one direction, and
only one of the side surfaces of each of the first circuit patterns, among the side surfaces of each of the first circuit patterns opposing each other in the one direction, is in contact with the second insulating layer.

48. The printed circuit board of claim 46, further comprising a seed metal layer disposed between one of the protruding portions of the first insulating layer and one of the first circuit layers.

49. The printed circuit board of claim 48, wherein each of the first circuit patterns includes side surfaces opposing each other in the one direction, and
among the side surfaces of each of the first circuit patterns opposing each other in the one direction, the seed layer is disposed only on one of the side surfaces.

50. The printed circuit board of claim 48, wherein among side surfaces of each of the first circuit patterns, the seed layer is in contact with only one of the side surfaces.

51. The printed circuit board of claim 46, wherein an upper surface of each of the first circuit patterns, an upper surface of the second insulating layer, and an upper surface of each of the protruding portions of the first insulating layer are substantially coplanar with each other.

52. The printed circuit board of claim 46, wherein a lower surface of each of the first circuit patterns and a lower surface of the second insulating layer are in contact with the base portion of the first insulating layer and are substantially coplanar with each other.
